(19) United States
(12) Patent Application Publication
(10) Pub. No.: US 2010/0059790 A1
(43) Pub. Date: Mar. 11, 2010

(54) NITRIDE-BASED SEMICONDUCTOR DEVICE AND METHOD OF MANUFACTURING THE SAME

(75) Inventor: Kunio Takeuchi, Joyo-shi (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/557,145

(22) Filed: Sep. 10, 2009

(30) Foreign Application Priority Data
Sep. 11, 2008 (JP) 2008-233909

(51) Int. Cl. H01L 33/00; H01L 31/0224; H01L 31/0264; H01L 21/20

(52) U.S. Cl. 257/103; 136/252; 438/26; 438/478; 257/E33.063; 257/E33.013; 257/E33.056; 257/E21.09

(57) ABSTRACT

A nitride-based semiconductor device includes an n-type nitride-based semiconductor layer, and an n-side electrode having a first metal layer made of Al, formed on a surface of the n-type nitride-based semiconductor layer and a second metal layer made of Hf formed so as to cover a surface of the first metal layer on a side opposite to the n-type nitride-based semiconductor layer.

### CROSS-REFERENCE TO RELATED APPLICATIONS

The priority application number JP2008-233909, Nitride-Based Semiconductor Device and Method of Manufacturing the Same, Sep. 11, 2008, Kunio Takeuchi, upon which this patent application is based is hereby incorporated by reference.

### BACKGROUND OF THE INVENTION

1. Field of the Invention

The present invention relates to a nitride-based semiconductor device and a method of manufacturing the same, and more particularly, it relates to a nitride-based semiconductor device comprising an electrode formed on a surface of an n-type nitride-based semiconductor layer and a method of manufacturing the same.

2. Description of the Background Art

A nitride-based semiconductor device comprising an electrode formed on a surface of an n-type nitride-based semiconductor layer and a method of manufacturing the same is known in general, as disclosed in Japanese Patent Laying-Open No. 2003-142732, for example.

The aforementioned Japanese Patent Laying-Open No. 2003-142732 discloses a nitride-based semiconductor device comprising an n-type nitride-based semiconductor layer and an ohmic electrode formed on a surface of the n-type nitride-based semiconductor layer, the ohmic electrode where a side in contact with the n-type nitride-based semiconductor layer is constituted by an alloyed layer of Hf and Al, and a method of manufacturing the same. In the nitride-based semiconductor device, an ohmic layer where Hf and Al are alloyed at a prescribed ratio (concentration) is formed in the vicinity of the interface between the n-type nitride-based semiconductor layer and an Hf layer by performing a step of forming the Hf layer having a prescribed thickness on the surface of the n-type nitride-based semiconductor layer and thereafter forming an Al layer having a prescribed thickness on the Hf layer and annealing the stacked Hf and Al layers under a prescribed temperature condition. Excellent ohmic contact is obtained by alloying Hf and Al at the prescribed ratio by annealing.

In the nitride-based semiconductor device and the method of manufacturing the same disclosed in the aforementioned Japanese Patent Laying-Open No. 2003-142732, however, a step of alloying Hf and Al by stacking the Hf layer and the Al layer on the surface of the n-type nitride-based semiconductor layer in this order and thereafter annealing the Hf layer and the Al layer at the prescribed temperature is disadvantageously required in order to obtain the excellent ohmic contact.

### SUMMARY OF THE INVENTION

A nitride-based semiconductor device according to a first aspect of the present invention comprises an n-type nitride-based semiconductor layer, and an n-side electrode including a first metal layer made of Al, formed on a surface of the n-type nitride-based semiconductor layer and a second metal layer made of Hf formed so as to cover a surface of the first metal layer on a side opposite to the n-type nitride-based semiconductor layer.

As hereinabove described, this nitride-based semiconductor device according to the first aspect of the present invention comprises the n-side electrode including the first metal layer made of Al formed on the surface of the n-type nitride-based semiconductor layer and the second metal layer made of Hf formed so as to cover the surface of the first metal layer on the side opposite to the n-type nitride-based semiconductor layer, whereby the n-side electrode has the structure in which the first metal layer made of Al and the second metal layer made of Hf are stacked in this order on the surface of the n-type nitride-based semiconductor layer without alloying, and hence the n-side electrode can be formed without requiring a thermal treatment step for alloying the first metal layer and the second metal layer at a constant ratio by controlling a prescribed temperature condition or time in the manufacturing process. Additionally, the first metal layer formed on the surface of the n-type nitride-based semiconductor layer is made of Al, whereby excellent ohmic contact with the n-type nitride-based semiconductor layer can be obtained by the first metal layer made of Al. Further, the second metal layer made of Hf is provided on the first metal layer made of Al, whereby the second metal layer made of Hf which is a high melting point metal can suppress deterioration of an ohmic contact characteristic due to a thermal treatment step added after forming the electrode.

In the aforementioned nitride-based semiconductor device according to the first aspect, the first metal layer is preferably formed to partially cover the surface of the n-type nitride-based semiconductor layer, and the second metal layer is preferably formed to cover the surface of the first metal layer, and a surface, not covered by the first metal layer, of the n-type nitride-based semiconductor layer. According to this structure, the second metal layer is formed with a portion covering the surface of the first metal layer and a portion covering the surface of the n-type nitride-based semiconductor layer. Thus, a surface area of the second metal layer on a side of the n-type nitride-based semiconductor layer can be increased and hence adhesiveness of the n-side electrode with respect to the surface of the n-type nitride-based semiconductor layer can be improved.

In this case, the first metal layer is preferably formed in a state where Al is distributed in the form of islands or a state where Al is in the form of a net. According to this structure, the second metal layer made of Hf covers the surface of the first metal layer made of Al provided in the form of islands or a net, and penetrates into a clearance between the first metal layer formed in the form of islands or a net and the n-type nitride-based semiconductor layer exposed from the first metal layer to cover the surface of the n-type nitride-based semiconductor layer, and hence the surface area of the second metal layer can be easily increased.

In the aforementioned structure in which Al in the first metal layer is formed in the form of islands or a net, a thickness of the islandlike or netlike first metal layer is preferably at most about 10 nm. According to this structure, the first metal layer made of Al can be easily formed on the surface of the n-type nitride-based semiconductor layer in the state of being in the form of islands or a net.

In the aforementioned structure in which Al in the first metal layer is formed in the form of islands or a net, the second metal layer is preferably formed to be in contact with the surface of the islandlike or netlike first metal layer and the surface, not covered by the first metal layer, of the n-type nitride-based semiconductor layer. According to this structure, the second metal layer made of Hf has regions not only covering the surface of the first metal layer made of Al but also in direct contact with the surface of the n-type nitride-based semiconductor layer, and hence adhesiveness of the n-side electrode to the surface of the n-type nitride-based semiconductor layer can be reliably improved by the second metal layer made of Hf. Thus, film separation of the n-side electrode can be suppressed also when the semiconductor device is successively subjected to prescribed manufacturing processes under a higher temperature condition than that in forming the n-side electrode (a heat treatment step at about 200° C. to about 300° C. such as a baking step by photolithography, or a step of wire-bonding to the n-side electrode, for example). This also can suppress the deterioration of the ohmic contact characteristic.

In this case, a thickness of the second metal layer is at least about 2 nm and not more than about 20 nm. According to this structure, excellent ohmic contact with the n-type nitride-based semiconductor layer can be obtained not only by the first metal layer but also by the second metal layer made of Hf.

In the aforementioned nitride-based semiconductor device according to the first aspect, the n-side electrode further preferably includes a third metal layer made of Pd, formed on a side of the second metal layer opposite to a side formed with the first metal layer. According to this structure, when a pad electrode layer made of Au is formed on the second metal layer for example, the pad electrode layer can be easily formed on the second metal layer through the third metal layer made of Pd in the n-side electrode.

In the aforementioned structure in which the n-side electrode includes the third metal layer, the n-side electrode preferably further includes a fourth metal layer formed between the second metal layer and the third metal layer, and the fourth metal layer preferably includes at least either Ti or Pt. According to this structure, the first metal layer and the second metal layer are covered by the fourth metal layer, and hence the fourth metal layer including at least either Ti or Pt can easily suppress a thermal influence on the first metal layer and the second metal layer resulting from the thermal treatment step (a heat treatment step at about 200° C. to about 300° C. such as a photolithography step or a baking step, a step of die-bonding a light-emitting device to a package (stem) by AuSn solder, or a step of wire-bonding to the n-side electrode) after forming the n-side electrode. Thus, the deterioration of the ohmic contact characteristic in the n-side electrode can be suppressed.

In the aforementioned structure in which the fourth metal layer includes at least either Ti or Pt, a thickness of the fourth metal layer is preferably larger than a thickness of the third metal layer. According to this structure, the fourth metal layer having larger thickness, arranged on a side closer than the third metal layer with respect to the first metal layer and the second metal layer which are an ohmic electrode layer can reliably suppress a thermal influence on the ohmic electrode layer.

In the aforementioned structure in which the fourth metal layer includes at least either Ti or Pt, the fourth metal layer is preferably made of Ti, and a thickness of the fourth metal layer is preferably at least about 100 nm and not more than about 150 nm. According to this structure, a suitable resistance value of the ohmic electrode layer (first metal and second metal layers) constituting the n-side electrode can be maintained regardless of presence/absence of thermal treatment after forming the n-side electrode.

In the aforementioned nitride-based semiconductor device according to the first aspect, the n-side electrode preferably further includes a pad electrode layer containing Au, formed on a side of the second metal layer opposite to the first metal layer. According to this structure, the pad electrode layer containing Au can easily inhibit an impact in die-bonding the n-side electrode of the nitride-based semiconductor device employed as a bonding surface to a heat radiator base (submount) or the like from directly transmitting to an ohmic electrode layer (first and second metal layers).

The aforementioned nitride-based semiconductor device according to the first aspect preferably further comprises a light emitting layer formed on a surface of the n-type nitride-based semiconductor layer on a side opposite to the n-side electrode and a p-type nitride-based semiconductor layer formed on a surface of the light emitting layer, wherein the nitride-based semiconductor device is preferably a semiconductor light-emitting device including the n-type nitride-based semiconductor layer, the light emitting layer and the p-type nitride-based semiconductor layer. According to this structure, the semiconductor light-emitting device having the n-side electrode obtaining excellent ohmic contact without thermal treatment can be formed.

The aforementioned nitride-based semiconductor device according to the first aspect preferably further comprises a p-type nitride-based semiconductor layer formed on a surface of the n-type nitride-based semiconductor layer on a side opposite to the n-side electrode, wherein the nitride-based semiconductor device is preferably a solar cell device including the n-type nitride-based semiconductor layer and the p-type nitride-based semiconductor layer. According to this structure, the solar cell device having the n-side electrode obtaining excellent ohmic contact without thermal treatment can be formed.

A method of manufacturing a nitride-based semiconductor device according to a second aspect of the present invention comprises steps of forming an n-type nitride-based semiconductor layer, and forming an n-side electrode by stacking a first metal layer made of Al and a second metal layer made of Hf covering a surface of the first metal layer on a side opposite to the n-type nitride-based semiconductor layer on a surface of the n-type nitride-based semiconductor layer.

As hereinabove described, this method of manufacturing a nitride-based semiconductor device according to the second aspect comprises the step of forming the n-side electrode by stacking the first metal layer made of Al and the second metal layer made of Hf covering the surface of the first metal layer on the side opposite to the n-type nitride-based semiconductor layer on the surface of the n-type nitride-based semiconductor layer, whereby the n-side electrode has the structure in which the first metal layer made of Al and the second metal layer made of Hf are stacked in this order on the surface of the n-type nitride-based semiconductor layer without alloying, and hence the nitride-based semiconductor device formed with the n-side electrode can be obtained without requiring a thermal treatment step for alloying the first metal layer and the second metal layer at a constant ratio by controlling a prescribed temperature condition or time in the manufacturing process. Additionally, the first metal layer made of Al is formed on the surface of the n-type nitride-based semiconductor layer, whereby excellent ohmic contact with the n-type nitride-based semiconductor layer can be obtained by the first metal layer made of Al. Further, the second metal layer made of Hf is formed on the first metal layer made of Al, whereby the second metal layer made of Hf which is a high melting point metal can suppress deterioration of an ohmic contact characteristic due to a thermal treatment step added after forming the electrode.

In the aforementioned method of manufacturing a nitride-based semiconductor device according to the second aspect, the step of forming the n-side electrode preferably includes a step of forming the first metal layer so as to partially cover the surface of the n-type nitride-based semiconductor layer and a step of forming the second metal layer so as to cover the surface of the first metal layer and a surface, not covered by the first metal layer, of the n-type nitride-based semiconductor layer. According to this structure, the second metal layer is formed with a portion covering the surface of the first metal layer and a portion covering the surface of the n-type nitride-based semiconductor layer. Thus, a surface area of the second metal layer on a side of the n-type nitride-based semiconductor layer can be increased and hence the n-side electrode having improved adhesiveness with respect to the surface of the n-type nitride-based semiconductor layer can be formed.

The aforementioned method of manufacturing a nitride-based semiconductor device according to the second aspect preferably further comprises steps of forming a semiconductor light-emitting device by stacking a light emitting layer and a p-type nitride-based semiconductor layer on a surface of the n-type nitride-based semiconductor layer on a side opposite to a side formed with the n-side electrode and bonding a surface of the semiconductor light-emitting device on side of the p-type nitride-based semiconductor layer to a surface of a support substrate in advance of the step of forming the n-side electrode. According to this structure, the semiconductor light-emitting device and the support substrate are bonded to each other by heating before the step of forming the n-side electrode requiring no thermal treatment step, and hence the n-side electrode in which a thermal influence on the ohmic electrode layer is reliably suppressed can be formed. Thus, the semiconductor light-emitting device having the n-side electrode obtaining excellent ohmic contact can be formed.

In this case, the step of forming the n-type nitride-based semiconductor layer preferably includes a step of forming the n-type nitride-based semiconductor layer on a surface of a growth substrate, and further comprises a step of removing the growth substrate from the semiconductor light-emitting device bonded on the surface of the support substrate in advance of the step of forming the n-side electrode. According to this structure, the n-side electrode in which a thermal influence on the ohmic electrode layer is reliably suppressed can be formed on the surface of the nitride-based semiconductor layer with the growth substrate removed, after removing the growth substrate from the semiconductor light emitting device bonded to the support substrate.

In the aforementioned method of manufacturing a nitride-based semiconductor device according to the second aspect, the step of forming the n-side electrode preferably includes a step of forming the n-side electrode without thermal treatment after stacking the first and second metal layers. According to this structure, the n-side electrode can be formed without thermal treatment for alloying the first and second metal layers at a constant ratio by controlling a prescribed temperature condition or time after stacking the first and second metal layers, and hence deterioration of the ohmic contact characteristics due to thermal treatment (thermal treatment temperature) for alloying can be suppressed.

The aforementioned method of manufacturing a nitride-based semiconductor device according to the second aspect preferably further comprises a step of thinning of said n-type semiconductor layer from a side of the surface of the n-type nitride-based semiconductor layer in advance of the step of forming the n-side electrode, and a step of removing a surface layer generated on the surface of the n-type nitride-based semiconductor layer by thinning. According to this structure, when forming the n-side electrode, the first metal layer can be formed on the surface of the n-type nitride-based semiconductor layer cleaned by removing the surface layer generated by thinning, and hence adhesiveness between the n-type nitride-based semiconductor layer and the n-side electrode (first metal layer) can be improved.

A method of manufacturing a nitride-based semiconductor device according to a third aspect of the present invention comprises steps of forming a nitride-based semiconductor stacked with an n-type nitride-based semiconductor layer and a p-type nitride-based semiconductor layer, forming a p-side electrode on a surface of the p-type nitride-based semiconductor layer and forming an n-side electrode after the step of forming the p-side electrode, wherein the step of forming the n-side electrode includes a step of forming the n-side electrode by stacking a first metal layer made of Al and a second metal layer made of Hf covering a surface of the first metal layer on a side opposite to the n-type nitride-based semiconductor layer on a surface of the n-type nitride-based semiconductor layer.

As hereinabove described, this method of manufacturing a nitride-based semiconductor device according to a third aspect of the present invention, the step of forming the n-side electrode includes the step of forming the n-side electrode by stacking the first metal layer made of Al and the second metal layer made of Hf covering the surface of the first metal layer on the side opposite to the n-type nitride-based semiconductor layer on the surface of the n-type nitride-based semiconductor layer, whereby the n-side electrode has the structure in which the first metal layer made of Al and the second metal layer made of Hf are stacked in this order on the surface of the n-type nitride-based semiconductor layer without alloying, and hence the nitride-based semiconductor device formed with the n-side electrode can be formed without requiring a thermal treatment step for alloying the first metal layer and the second metal layer at a constant ratio by controlling a prescribed temperature condition or time in the manufacturing process. Additionally, the first metal layer made of Al is formed on the surface of the n-type nitride-based semiconductor layer, whereby excellent ohmic contact with the n-type nitride-based semiconductor layer can be obtained by the first metal layer made of Al. Further, the second metal layer made of Hf is formed on the first metal layer made of Al, whereby the second metal layer made of Hf which is a high melting point metal can suppress deterioration of an ohmic contact characteristic due to a thermal treatment step added after forming the electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a structure of a semiconductor laser device according to a first embodiment of the present invention;

FIG. 2 is an enlarged sectional view showing a detailed structure of an n-side electrode of the semiconductor laser device according to the first embodiment of the present invention;

FIG. 3 is a plan view showing a detailed structure of the n-side electrode of the semiconductor laser device according to the first embodiment of the present invention;

FIG. 4 is a diagram for illustrating a manufacturing process for a blue-violet semiconductor laser device according to the first embodiment of the present invention;

FIG. 5 is a front elevational view showing a structure of a semiconductor laser device according to a second embodiment of the present invention;

FIG. 6 is an enlarged sectional view showing the structure of the semiconductor laser device according to the second embodiment of the present invention;

FIGS. 7 to 9 are diagrams for illustrating a manufacturing process for the semiconductor laser device according to the second embodiment of the present invention;

FIG. 10 is a sectional view showing a structure of a transferred-layer type LED chip according to a third embodiment of the present invention;

FIG. 11 is an enlarged sectional view showing a detailed structure of a semiconductor layer of the transferred-layer type LED chip according to the third embodiment of the present invention;

FIGS. 12 and 13 are diagrams for illustrating a manufacturing process for the transferred-layer type LED chip according to the third embodiment of the present invention;

FIG. 14 is a sectional view showing a structure of a solar cell device according to a fourth embodiment of the present invention;

FIG. 15 is a diagram showing materials and formation methods of n-side electrodes prepared in Examples and comparative examples of the present invention;

FIG. 16 is a diagram showing the contents of comparative experiments of the n-side electrodes prepared in the Examples and the comparative examples of the present invention;

FIGS. 17 to 21 are diagrams showing results of the comparative experiment conducted for confirming characteristics of the n-side electrodes according to the present invention;

FIG. 22 is a diagram showing measurement results conducted for confirming ohmic characteristics of the n-side electrodes according to the present invention;

FIG. 23 is a diagram showing results of an experiment conducted for studying an optimum value of a thickness of a Ti layer constituting the n-side electrode according to the present invention;

FIG. 24 is a diagram showing results of a operation test of blue-violet semiconductor laser devices to which a conventional n-side electrode is applied; and

FIG. 25 is a diagram showing results of a operation test of a blue-violet semiconductor laser device to which the n-side electrode according to the present invention is applied.

### DESCRIPTION OF THE PREFERRED EMBODIMENTS

### Embodiments

Embodiments of the present invention will be hereinafter described with reference to the drawings.

### First Embodiment

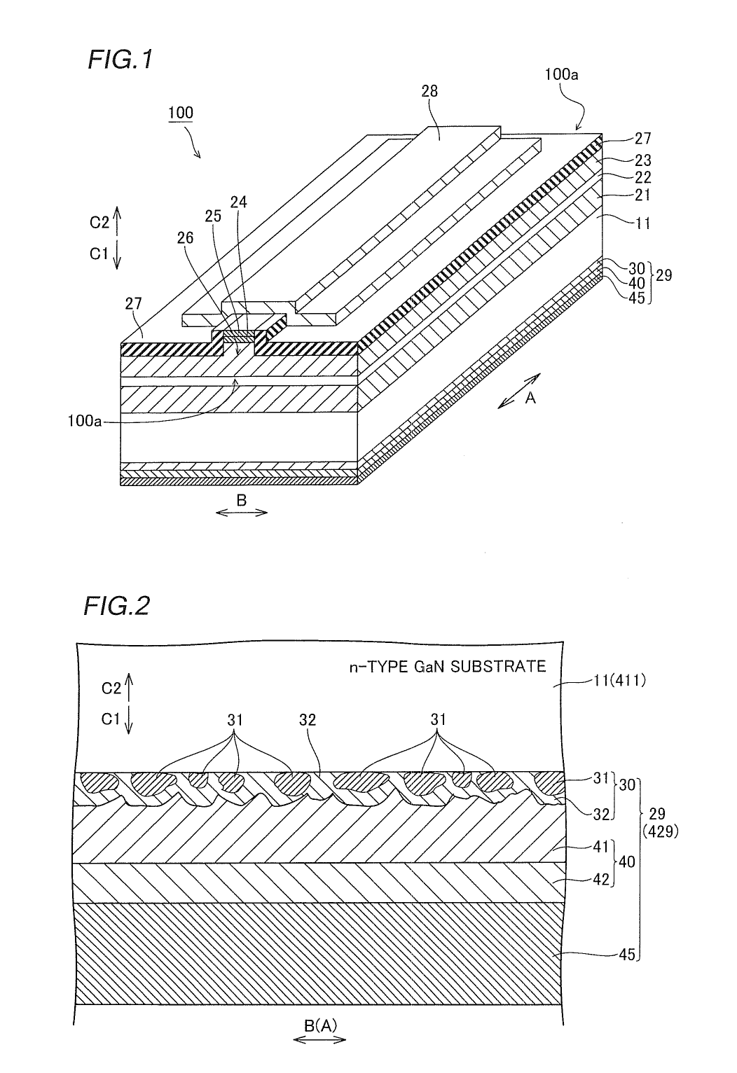

A structure of a blue-violet semiconductor laser device 100 according to a first embodiment of the present invention will be now described with reference to FIGS. 1 to 3. According to the first embodiment, the present invention is applied to the blue-violet semiconductor laser device 100 which is an exemplary nitride-based semiconductor laser device. The blue-violet semiconductor laser device 100 is an example of the “semiconductor light-emitting device” in the present invention.

In the blue-violet semiconductor laser device 100 according to the first embodiment of the present invention, an n-type cladding layer 21 made of n-type AlGaN is formed on an n-type GaN substrate 11 made of GaN as shown in FIG. 1. An active layer 22 having a multiple quantum well (MQW), obtained by alternately stacking four barrier layers (not shown) consisting of undoped GaInN and three well layers (not shown) consisting of undoped GaInN is formed on the n-type cladding layer 21. A p-type cladding layer 23 made of p-type AlGaN is formed on the active layer 22. A p-side contact layer 24 made of undoped GaInN is formed on a projecting portion of the p-type cladding layer 23. A p-side ohmic electrode 25 made of a Pd layer, a Pt layer and an Au layer successively from a side closer to the p-side contact layer 24 is formed on the p-side contact layer 24. The n-type GaN substrate 11 and the n-type cladding layer 21 are examples of the “n-type nitride-based semiconductor layer” in the present invention. The active layer 22 is an example of the “light emitting layer” in the present invention, and the p-type cladding layer 23 is an example of the “p-type nitride-based semiconductor layer” in the present invention.

As shown in FIG. 1, the p-type cladding layer 23 has a projecting portion forming on a substantially central portion of the device and extending in a cavity direction (direction A) and planar portions extending to both sides (direction B) of the projecting portion. A ridge 26 for constituting an optical waveguide is formed by the projecting portion of the p-type cladding layer 23. The ridge 26 has a width of about 1.5 μm in a width direction (direction B) of the blue-violet semiconductor laser device 100 and is so formed as to extend along the cavity direction (direction A) in a striped manner.

A current blocking layer 27 made of SiO₂ is formed to cover upper surfaces of the planar portions of the p-type cladding layer 23 and side surfaces (both side surfaces of the projecting portion of the p-type cladding layer 23 and the p-side contact layer 24) of the ridge 26. The p-side pad electrode 28 made of Au is formed to cover prescribed regions on the upper surfaces of the p-side ohmic electrode 25 and the current blocking layer 27. An n-side electrode 29 is formed on a lower surface of the n-type GaN substrate 11.

According to the first embodiment, an n-side electrode 29 has a structure in which an ohmic electrode layer 30, a barrier layer 40 and a pad electrode layer 45 are stacked successively from a side closer to the n-type GaN substrate 11, as shown in FIG. 2. In the ohmic electrode layer 30, an Al layer 31 having a thickness of about 6 nm and an Hf layer 32 having a thickness of about 10 nm are stacked successively from a side closer to the n-type GaN substrate 11. The Al layer 31 and the Hf layer 32 are examples of the “first metal layer” and the “second metal layer” in the present invention, respectively.

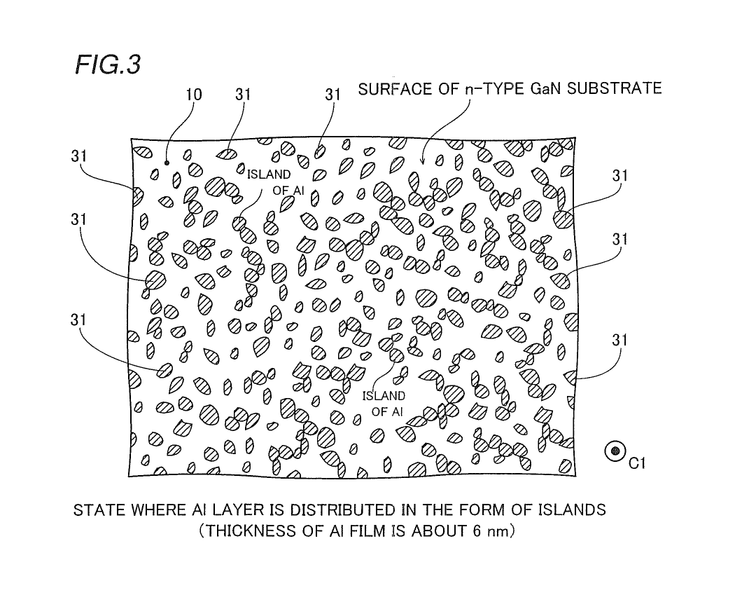

According to the first embodiment, the Al layer 31 having a thickness of about 6 nm is formed in a state of being distributed in the form of islands on a surface of the n-type GaN substrate 11 (see FIG. 2) in plan view and is not in the form of a completely continuous film, as shown in FIG. 3. When the Al layer 31 has a thickness of about 6 nm, a portion formed in the form of a net by connecting parts of the adjacent islands of Al also exists. As shown in FIG. 2, the Hf layer 32 covering the Al layer 31 is formed on an interface between the n-type GaN substrate 11 and the ohmic electrode layer 30 to be in contact with the surface of the n-type GaN substrate 11 in addition to the Al layer 31 distributed in the form of islands. Therefore, the ohmic electrode layer 30 is so formed that both of the Al layer 31 distributed in the form of islands and the Hf layer 32 are in contact with the surface of the n-type GaN substrate 11. The Al layer 31 in a state where Al is distributed in the form of islands is preferably formed to have a thickness of at most about 10 nm. The Hf layer 32 covering the Al layer 31 is formed to preferably have a thickness of at least about 2 nm and not more than about 20 nm, and more preferably have a thickness of at most about 10 nm.

According to the first embodiment, in the barrier layer 40, a Ti layer 41 having a thickness of about 150 nm and a Pd layer 42 having a thickness of about 20 nm are stacked in this order on the ohmic electrode layer 30. The pad electrode layer 45 made of Au having a thickness of about 300 nm is formed on the barrier layer 40. Each of the Ti layer 41 and the Pd layer 42 has a barrier function for preventing reaction by thermal treatment of the ohmic electrode layer 30 (Al and Hf layers 31 and 32) and the pad electrode layer 45. The Ti layer 41 constituting the barrier layer 40 is formed to preferably have a thickness of about at most 150 nm. The Ti layer 41 is an example of the “fourth metal layer” in the present invention, and the Pd layer 42 is an example of the “third metal layer” in the present invention.

In the blue-violet semiconductor laser device 100, a pair of cavity facets 100a substantially perpendicular to a main surface (upper surface) of the n-type GaN substrate 11 are formed on both ends of the cavity direction (direction A), as shown in FIG. 1. Dielectric multilayer films (not shown) made of AlN or AlO₃ are formed on the pair of cavity facets 100a by facet coating treatment in a manufacturing process. A multilayer film made of GaN, AlN, BN, Al₂O₃, SiO₂, ZrO₂, Ta₂O₅, Nb₂O₅, La₂O₃, SiN, AlON and MgF₂, or Ti₃O₅ or Nb₂O₃ which is a material different in an alloyed ratio from these can be employed for the dielectric multilayer film.

A manufacturing process for the blue-violet semiconductor laser device 100 according to the first embodiment will be now described with reference to FIGS. 1 to 4.

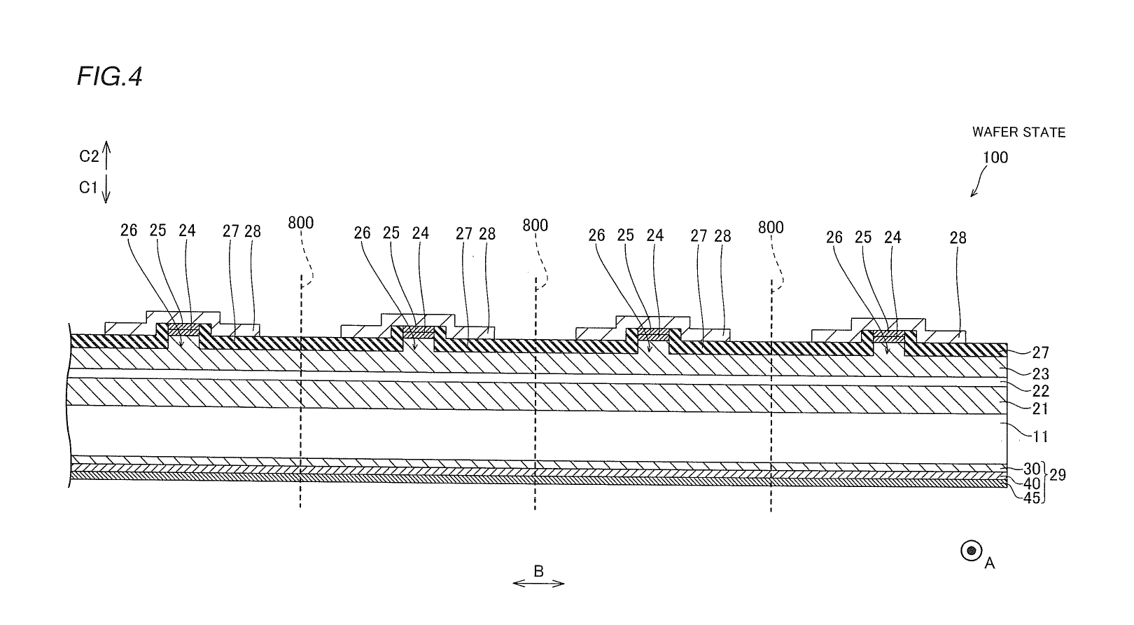

In the manufacturing process of the blue-violet semiconductor laser device 100 according to the first embodiment, the n-type cladding layer 21, the active layer 22, the p-type cladding layer 23, the p-side contact layer 24 and the p-side ohmic electrode 25 are successively stacked on the upper surface of the n-type GaN substrate 11 by metal organic chemical vapor deposition (MOCVD) as shown in FIG. 4. Then, the p-side ohmic electrode 25, the p-side contact layer 24 and the p-type cladding layer 23 are partially etched to form the ridges 26, and the current blocking layer 27 is formed to cover from the both side surfaces of the ridges 26 to the planar portions of the p-type cladding layer 23. Thereafter, the p-side pad electrode 28 is formed to cover the prescribed regions on the ridges 26 and the current blocking layer 27.

Then, the lower surface of the n-type GaN substrate 11 is so polished that the n-type GaN substrate 11 has a prescribed thickness and a damage layer due to polishing is removed by dry etching, and the n-side electrode 29 is thereafter formed on the lower surface of the n-type GaN substrate 11, as shown in FIG. 4. The damage layer is an example of the “surface layer generated on a surface of an n-type nitride-based semiconductor layer by thinning” in the present invention. Thus, when forming the n-side electrode 29, the Al layer 31 is first stacked on the lower surface of the n-type GaN substrate 11 cleaned by removing the damage layer by polishing, and hence adhesiveness between the n-type GaN substrate 11 and the n-side electrode 29 (Al and Hf layers 31 and 32) is improved.

In the manufacturing process of the first embodiment, the Al layer 31 having a thickness of about 6 nm is evaporated on the lower surface of the n-type GaN substrate 11 in a vacuum held at about 30° C. by vacuum chamber as shown in FIG. 2. At this time, the Al layer 31 is formed on the surface of the n-type GaN substrate 11 in a state of being distributed in the form of islands (including a case of locally being in the form of a net), as shown in FIG. 3. Thereafter, the ohmic electrode layer 30 is so formed by evaporating the Hf layer 32 having a thickness of about 10 nm as to cover the Al layer 31 distributed in the form of islands. Consequently, the ohmic electrode layer 30 is so formed that both of the Al layer 31 distributed in the form of islands and the Hf layer 32 are in contact with the surface of the n-type GaN substrate 11, as shown in FIG. 2.

The Ti layer 41 having a thickness of about 150 nm and the Pd layer 42 having a thickness of about 20 nm are stacked in this order on the ohmic electrode layer 30 by vacuum chamber, thereby forming the barrier layer 40. Thereafter, the pad electrode layer 45 made of Au having a thickness of about 300 nm is formed on the barrier layer 40. Thus, the n-side electrode 29 in which the barrier layer 40 and the pad electrode layer 45 are stacked on the ohmic electrode layer 30 is formed.

As hereinabove described, in the manufacturing process of the first embodiment, when the n-side electrode 29 is formed, the ohmic electrode layer 30 is formed without thermal treatment for alloying after stacking the Al layer 31 and the Hf layer 32, and hence deterioration of the ohmic electrode layer 30 is suppressed. Thus, the blue-violet semiconductor laser device 100 in a wafer state shown in FIG. 4 is formed.

The wafer is cleaved in the direction B in the form of a bar to have a cavity length (L=about 800 μm), and division (separation) of the wafer into device is performed along the cavity direction (direction A (see FIG. 4)) on positions shown by broken lines 800. Thus, a large number of the blue-violet semiconductor laser devices 100 according to the first embodiment shown in FIG. 1 are formed.

According to the first embodiment, as hereinabove described, the blue-violet semiconductor laser devices 100 comprises the n-side electrode 29 including the Al layer 31 formed on the lower surface of the n-type GaN substrate 11 and the Hf layer 32 formed to cover the surface of the Al layer 31 on a side opposite to the n-type GaN substrate 11, whereby the n-side electrode 29 has the ohmic electrode layer 30 in which the Al layer 31 and the Hf layer 32 are stacked in this order on the surface of the n-type GaN substrate 11 without alloying, and hence the n-side electrode 29 can be formed without requiring a thermal treatment step for alloying the Al layer 31 and the Hf layer 32 at a constant ratio by controlling a prescribed temperature condition or time in the manufacturing process. Additionally, the Al layer 31 is formed on the surface of the n-type GaN substrate 11, whereby excellent ohmic contact with the n-type GaN substrate 11 can be obtained by the Al layer 31. Further, the Hf layer 32 is provided on the Al layer 31, whereby the Hf layer 32 made of Hf which is a high melting point metal can suppress deterioration of an ohmic contact characteristic due to a thermal treatment step added after forming the n-side electrode 29. A thermal treatment step is not performed in forming the n-side electrode 29, and hence no thermal influence is not given to the p-side ohmic electrode 25. Thus, deterioration of the p-side ohmic electrode 25 due to a thermal treatment temperature is suppressed and hence increase in a voltage of the laser device is suppressed.

According to the first embodiment, the Al layer 31 is so formed as to partially cover the lower surface of the n-type GaN substrate 11, and the Hf layer 32 is so formed as to cover the surface of the Al layer 31 and the lower surface, not covered by the Al layer 31, of the n-type GaN substrate 11, whereby the Hf layer 32 includes a portion covering the surface of the Al layer 31 and a portion covering the surface of the n-type GaN substrate 11. Thus, a surface area of the Hf layer 32 on a side of the n-type GaN substrate 11 can be increased and hence adhesiveness of the n-side electrode 29 with respect to the surface of the n-type GaN substrate 11 can be improved.

According to the first embodiment, the Al layer 31 is formed in the state where Al is distributed in the form of islands or in the state of being in the form of a net, whereby the Hf layer 32 covers the surface of the Al layer 31 provided in the form of islands or a net, and penetrates into a clearance between the Al layer 31 formed in the form of islands or a net and the n-type GaN substrate 11 exposed from the Al layer 31 to cover the surface of the n-type GaN substrate 11, and hence the surface area of the Hf layer 32 can be easily increased.

According to the first embodiment, the thickness of the Al layer 31 provided in the form of islands or a net is at most about 10 nm, whereby the Al layer 31 can be easily formed on the lower surface of the n-type GaN substrate 11 in the state of being in the form of islands or a net.

According to the first embodiment, the Hf layer 32 is formed to be in contact with the surface of the Al layer 31 formed in the form of islands or a net and the surface, not covered by the Al layer 31, of the n-type GaN substrate 11, whereby the Hf layer 32 not only covers the surface of the Al layer 31 but also has regions in direct contact with the surface of the n-type GaN substrate 11, and hence adhesiveness of the n-side electrode 29 to the surface of the n-type GaN substrate 11 can be reliably improved by the Hf layer 32. Thus, film separation of the n-side electrode 29 can be suppressed also when the blue-violet semiconductor laser device 100 is successively subjected to the prescribed manufacturing processes under a higher temperature condition than that in forming the n-side electrode 29 (a heat treatment step at about 200° C. to about 300° C. such as a baking step by photolithography, or a step of wire-bonding to the n-side electrode 29, for example). This also can suppress the deterioration of the ohmic contact characteristic.

According to the first embodiment, the thickness of the Hf layer 32 is at most about 20 nm, whereby excellent ohmic contact with the n-type GaN substrate 11 can be obtained not only by the Al layer 31 but also by the Hf layer 32.

According to the first embodiment, the Pd layer 42 is formed on a side of the Hf layer 32 opposite to a side on which the Al layer 31 is formed, whereby the pad electrode layer 45 can be easily formed on the Hf layer 32 through the Pd layer 42 in the n-side electrode 29 when forming the pad electrode layer 45 made of Au on the Hf layer 32.

According to the first embodiment, the Ti layer 41 is formed between the Hf layer 32 and the Pd layer 42 in the n-side electrode 29, whereby the Al layer 31 and the Hf layer 32 are covered by the Ti layer 41 having the barrier function, and hence the Ti layer 41 can easily suppress a thermal influence on the Al layer 31 and the Hf layer 32 resulting from the thermal treatment step (a heat treatment step at about 200° C. to about 300° C. such as a photolithography step or a baking step, a step of die-bonding a light-emitting device to a package (stem) by AuSn solder, or a step of wire-bonding to the n-side electrode 29) after forming the n-side electrode 29. Thus, the deterioration of the ohmic contact characteristic in the n-side electrode 29 can be suppressed.

According to the first embodiment, the thickness of the Ti layer 41 (about 150 nm) is larger than the thickness of the Pd layer 42 (about 20 nm), whereby the Ti layer 41 having larger thickness, arranged on a side closer than the Pd layer 42 with respect to the ohmic electrode layer 30 can reliably suppress a thermal influence on the ohmic electrode layer 30.

According to the first embodiment, the Ti layer 41 having a thickness of about 150 nm is formed, whereby a suitable resistance value of the ohmic electrode layer 30 constituting the n-side electrode 29 can be maintained regardless of presence/absence of thermal treatment after forming the n-side electrode 29.

According to the first embodiment, the n-side electrode 29 includes the pad electrode layer 45 made of Au, formed on the surface of the barrier layer 40 on a side opposite to the ohmic electrode layer 30, whereby the pad electrode layer 45 can easily inhibit an impact in die-bonding the side of the n-side electrode 29 of the nitride-based semiconductor device 100 employed as a bonding surface to a heat radiator base (submount) or the like from directly transmitting to an ohmic electrode layer 30 (Al and Hf layers 31 and 32).

According to the first embodiment, the blue-violet semiconductor laser device 100, to which the “n-side electrode” of the present invention is applied, is formed, whereby the semiconductor laser device having the n-side electrode 29 obtaining excellent ohmic contact without thermal treatment (alloying) can be formed.

### Second Embodiment

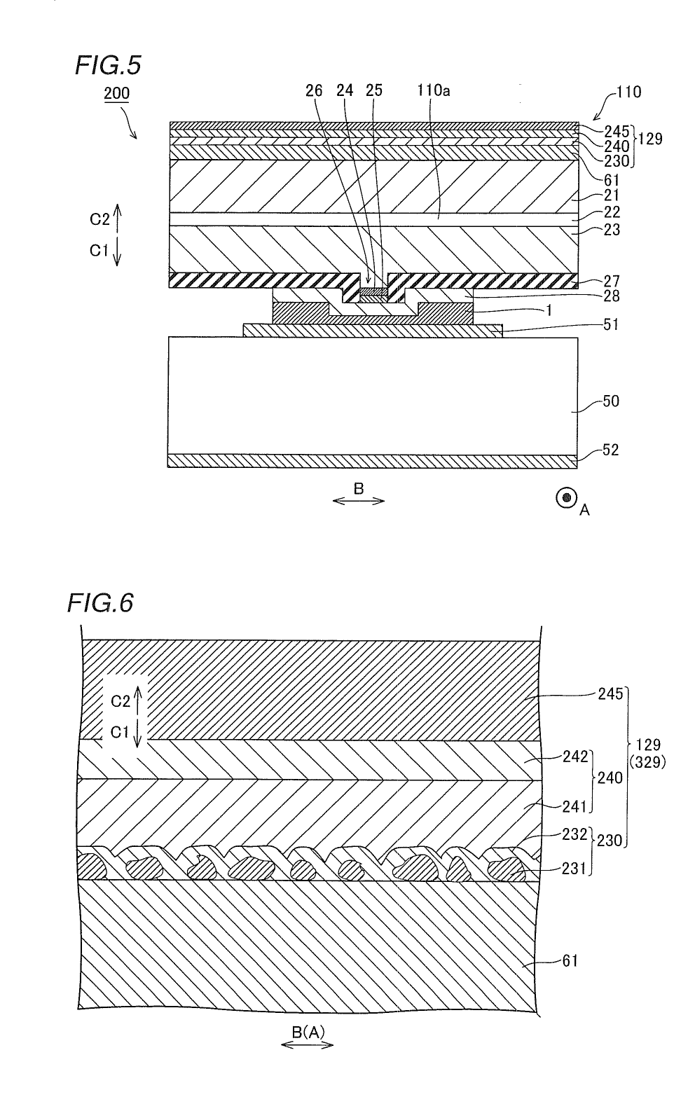

Referring to FIGS. 5 and 6, according to a second embodiment, a blue-violet semiconductor laser device portion 110 is bonded to a surface of a p-type Ge substrate 50 through a conductive fusible layer 1, dissimilarly to the aforementioned first embodiment. The p-type Ge substrate 50 is an example of the “support substrate” in the present invention.

In a semiconductor laser device 200 according to the second embodiment of the present invention, a blue-violet semiconductor laser device portion 110 having a thickness of about 5 μm is bonded to an upper surface of the p-type Ge substrate 50 having a thickness of about 100 μm through a fusible layer 1, as shown in FIG. 5.

In the blue-violet semiconductor laser device portion 110, an active layer 22 obtained by alternately stacking four barrier layers (not shown) and three well layers (not shown), a p-type cladding layer 23 and a p-type contact layer 24 are formed in this order on a lower surface of an n-type cladding layer 21, as shown in FIG. 5. A p-side ohmic electrode 25 made of a Pd layer, a Pt layer and an Au layer successively from a side closer to the p-side contact layer 24 is formed on a lower surface of the p-side contact layer 24. The semiconductor laser device 200 is an example of the “semiconductor light-emitting device” in the present invention.

As shown in FIG. 5, a ridge 26 for constituting an optical waveguide is formed by the projecting portion of the p-type cladding layer 23. A current blocking layer 27 is formed to cover lower surfaces of planar portions of the p-type cladding layer 23 and side surfaces of the ridge 26. A p-side pad electrode 28 is formed on both sides of the ridge 26 to cover regions on the lower surfaces of the p-side ohmic electrode 25 and the current blocking layer 27.

An n-side electrode 129 is formed on an upper surface of the n-type cladding layer 21 through an n-type GaN layer 61 (n-side contact layer). The n-type GaN layer 61 is an exemplary n-type nitride-based semiconductor layer of the present invention.

According to the second embodiment, an n-side electrode 129 has a structure in which an ohmic electrode layer 230, a barrier layer 240 and a pad electrode layer 245 are stacked successively from a side closer to the n-type GaN layer 61, as shown in FIG. 6. In the ohmic electrode layer 230, an Al layer 231 having a thickness of about 6 nm and an Hf layer 232 having a thickness of about 10 nm are stacked successively from a side closer to the n-type GaN layer 61. The Al layer 231 and the Hf layer 232 are examples of the “first metal layer” and the “second metal layer” in the present invention, respectively.

Also in the second embodiment, the Al layer 231 is formed in a state of being distributed in the form of islands on a surface of the n-type GaN layer 61 (see FIG. 6). The Hf layer 232 covering the Al layer 231 is also formed on an interface between the n-type GaN layer 61 and the ohmic electrode layer 230 to be in contact with the surface of the n-type GaN layer 61 in addition to the Al layer 231 distributed in the form of islands. Therefore, the ohmic electrode layer 230 is so formed that both of the Al layer 231 distributed in the form of islands and the Hf layer 232 are in contact with the surface of the n-type GaN layer 61, as shown in FIG. 6.

According to the second embodiment, in the barrier layer 240, a Pt layer 241 having a thickness of about 20 nm and a Pd layer 242 having a thickness of about 20 nm are stacked in this order on the ohmic electrode layer 230. The pad electrode layer 245 made of Au having a thickness of about 300 nm is formed on the barrier layer 240. Each of the Pt layer 241 and the Pd layer 242 has a barrier function for preventing reaction by thermal treatment of the ohmic electrode layer 230 (Al and Hf layers 231 and 232) and the pad electrode layer 245. The Pt layer 241 is an example of the “fourth metal layer” in the present invention, and the Pd layer 242 is an example of the “third metal layer” in the present invention.

A p-side ohmic electrode 51 made of an Ni layer having a thickness about 150 nm and an Au layer having a thickness of about 300 nm is formed successively from a side closer to the p-type Ge substrate 50 on a prescribed region of the upper surface of the p-type Ge substrate 50, as shown in FIG. 5. An anode-side electrode 52 made of an Ni layer having a thickness about 100 nm and an Au layer having a thickness of about 300 nm is formed successively from a side closer to the p-type Ge substrate 50 on a lower surface of the p-type Ge substrate 50.

In the blue-violet semiconductor laser device 110, a pair of cavity facets 110a substantially perpendicular to a main surface (upper surface) of the p-type Ge substrate 50 are formed on both ends of a cavity direction (direction A), as shown in FIG. 5.

A manufacturing process for the semiconductor laser device 200 according to the second embodiment will be now described with reference to FIGS. 5 to 9.

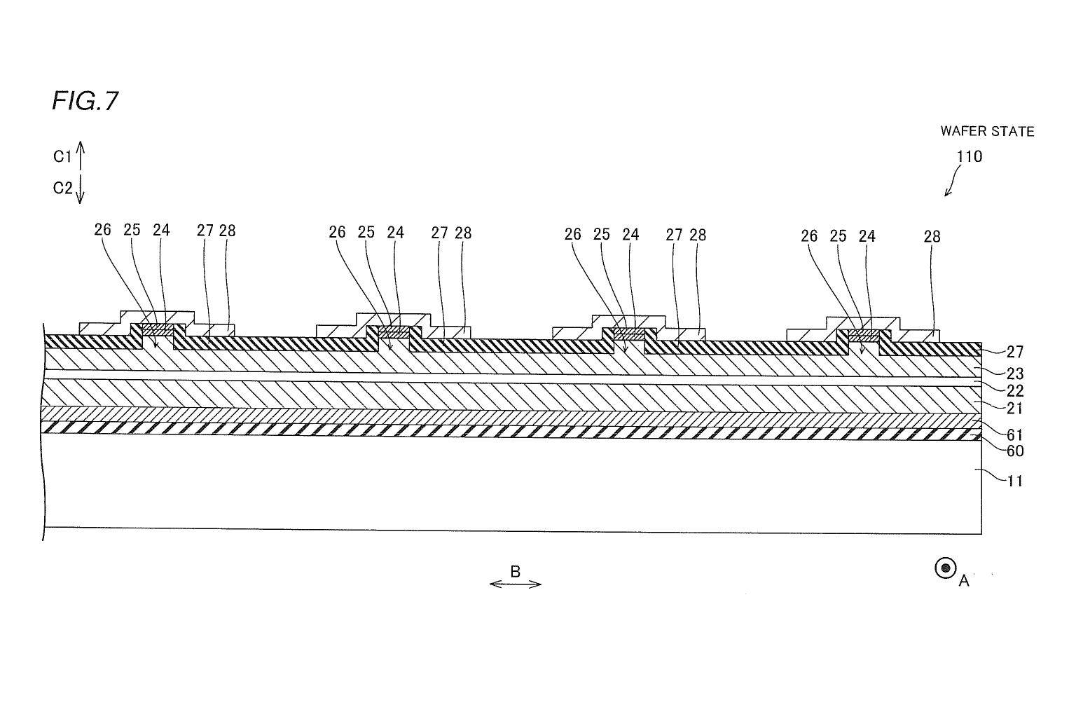

A separative layer 60, the n-type GaN layer 61, the n-type cladding layer 21, the active layer 22, the p-type cladding layer 23, the p-type contact layer 24 and the p-side ohmic electrode 25 are successively stacked on the upper surface of the n-type GaN substrate 11 employing a manufacturing method similar to that of the aforementioned first embodiment as shown in FIG. 7. Then, the ridges 26 are formed by etching and the current blocking layer 27 is so formed as to cover the planar portions of the p-type cladding layer 23 from the both side surfaces of the ridges 26. Thereafter, the p-side pad electrode 28 is so formed as to cover prescribed regions of the ridges 26 and the current blocking layer 27. Thus, a wafer formed with the blue-violet semiconductor laser device portion 110 except the n-side electrode 129 is prepared. The n-type GaN substrate 11 is an example of the “growth substrate” in the present invention.

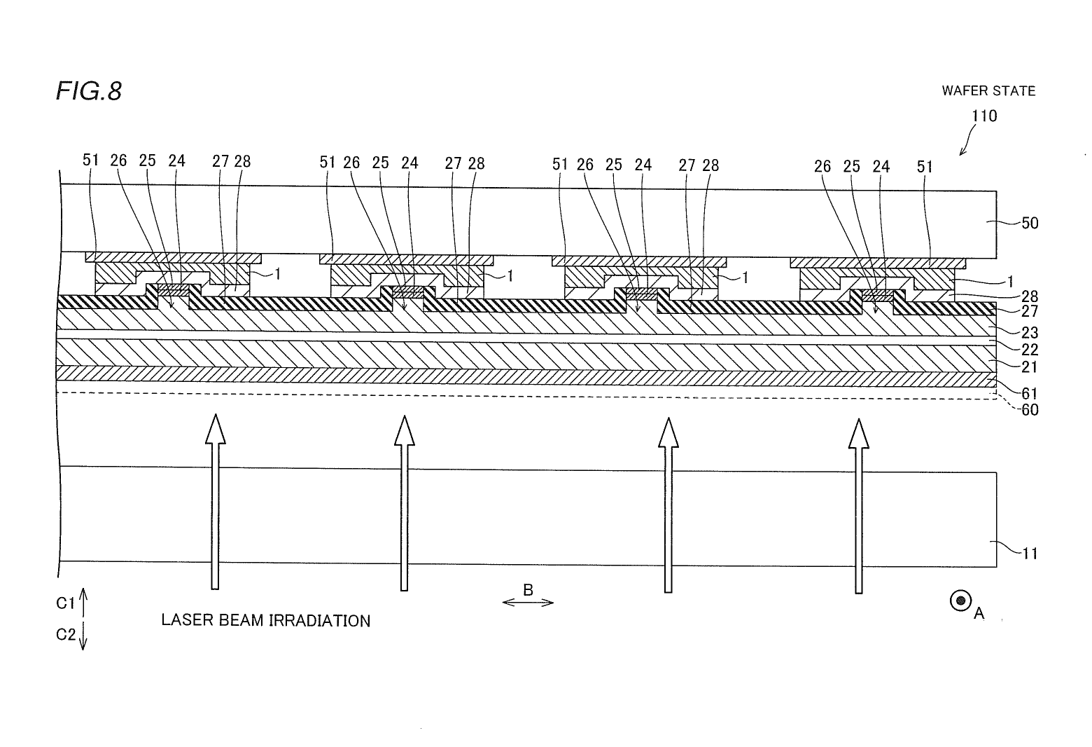

As shown in FIG. 8, the p-type Ge substrate 50 previously formed with the p-side ohmic electrode 51 made of the Ni layer and the Au layer and the fusible layer 1, and the wafer formed with the blue-violet semiconductor laser device portion 110 are bonded to each other by the fusible layer 1 while being opposed to each other. Then, second harmonics of an Nd:YAG laser beam (wavelength: about 532 nm) are applied only to the separative layer 60 (shown by broken lines) from a back surface (lower surface) of the n-type GaN substrate 11 upward, to decompose and evaporate the separative layer 60, as shown in FIG. 8. Thus, the n-type GaN substrate 11 is separated from the n-type GaN layer 61 along a breakdown region of the separative layer 60. Thereafter, the lower surface of the n-type GaN layer 61 is etched and cleaned, and the n-side electrode 129 is formed on the lower surface of the n-type GaN layer 61 by vacuum chamber.

In the manufacturing process of the second embodiment, the Al layer 231 having a thickness of about 6 nm is evaporated on the upper surface of the n-type GaN layer 61 in a vacuum held at about 30° C. by vacuum chamber as shown in FIG. 6. At this time, the Al layer 231 is formed on the surface of the n-type GaN layer 61 in a state of being distributed in the form of islands (including a case of locally being in the form of a net). Thereafter, the ohmic electrode layer 230 is so formed by evaporating the Hf layer 232 having a thickness of about 10 nm as to cover the Al layer 231 distributed in the form of islands. Consequently, the ohmic electrode layer 230 is so formed that both of the Al layer 231 distributed in the form of islands and the Hf layer 232 are in contact with the surface of the n-type GaN layer 61.

The Pt layer 241 having a thickness of about 20 nm and the Pd layer 242 having a thickness of about 20 nm are stacked in this order on the ohmic electrode layer 230 by vacuum chamber, thereby forming the barrier layer 240. Thereafter, the pad electrode layer 245 made of Au having a thickness of about 300 nm is formed on the barrier layer 240. Thus, the n-side electrode 129 in which the barrier layer 240 and the pad electrode layer 245 are stacked on the ohmic electrode layer 230 is formed.

In other words, in the manufacturing process of the second embodiment, the blue-violet semiconductor laser device portion 110 and the p-type Ge substrate 50 are bonded to each other by heating before forming the n-side electrode 129 requiring no thermal treatment step, and a Nd:YAG laser beam is applied, to separate the n-type GaN substrate 11 from the n-type GaN layer 61. Thus, the n-side electrode 129 in which a thermal influence on the ohmic electrode layer 230 is reliably suppressed is formed on the surface of the n-type GaN layer 61 with the n-type GaN substrate removed.

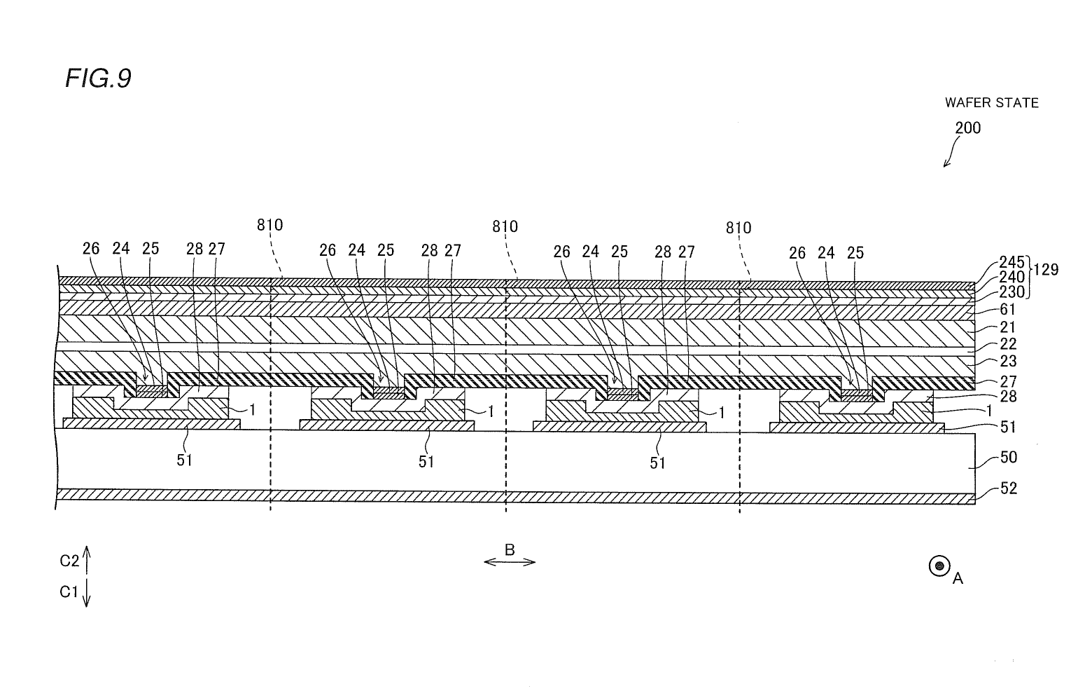

As shown in FIG. 9, the anode-side electrode 52 made of the Ni layer and the Au layer is formed on the lower surface of the p-type Ge substrate 50 adjusted to have a thickness of about 100 μm by polishing or etching, by vacuum chamber. Thus, the semiconductor laser device 200 in a state of a wafer shown in FIG. 9 is formed.

Then, the wafer is cleaved in a direction perpendicular to the cavity direction (direction B) in the form of a bar to have a prescribed cavity length, and division (separation) of the wafer into device is performed along the cavity direction (direction A) on positions shown by broken lines 800. Thus, a large number of the semiconductor laser devices 200 according to the second embodiment shown in FIG. 5 are formed.

According to the second embodiment, as hereinabove described, the blue-violet semiconductor laser device 200 comprises the n-side electrode 129 including the Al layer 231 formed on the surface of the n-type GaN layer 61 and the Hf layer 232 formed to cover the surface of the Al layer 231 on a side opposite to the n-type GaN layer 61, whereby the n-side electrode 129 has the ohmic electrode layer 230 in which the Al layer 231 and the Hf layer 232 are stacked in this order on the surface of the n-type GaN layer 61 without alloying, and hence the n-side electrode 129 can be formed without requiring a thermal treatment step for alloying the Al layer 231 and the Hf layer 232 at a constant ratio by controlling a prescribed temperature condition or time after forming the p-side electrode or the electrode on the side of the p-type Ge substrate in the manufacturing process. Additionally, the Al layer 231 is formed on the surface of the n-type GaN layer 61, whereby excellent ohmic contact with the n-type GaN layer 61 can be obtained by the Al layer 231. Further, the Hf layer 232 is provided on the Al layer 231, whereby the Hf layer 232 made of Hf which is a high melting point metal can suppress deterioration of an ohmic contact characteristic due to a thermal treatment step added after forming the n-side electrode 129. A thermal treatment step is not performed in forming the n-side electrode 129, and hence no thermal influence is not given not only to the p-side ohmic electrode 25 but also to the p-side ohmic electrode 51. Thus, deterioration of the p-side ohmic electrode 25 or 51 due to a thermal treatment temperature is suppressed and hence increase in a voltage of the laser device is suppressed.

According to the second embodiment, in the n-side electrode 129, the Pd layer 242 is formed on a side of the Hf layer 232 opposite to a side on which the Al layer 231 is formed, whereby the pad electrode layer 245 can be easily formed on the Hf layer 232 through the Pd layer 242 when forming the pad electrode layer 245 made of Au on the Hf layer 232.

According to the second embodiment, the Pt layer 241 is formed between the Hf layer 232 and the Pd layer 242 in the n-side electrode 129, whereby the Al layer 231 and the Hf layer 232 are covered by the Pt layer 241 having the barrier function, and hence the Pt layer 241 can easily suppress a thermal influence on the Al layer 231 and the Hf layer 232 resulting from the thermal treatment step (a heat treatment step at about 200° C. to about 300° C. such as a photolithography step or a baking step, a step of die-bonding a light-emitting device to a package (stem) by AuSn solder, or a step of wire-bonding to the n-side electrode 29) after forming the n-side electrode 129. Thus, the deterioration of the ohmic contact characteristic in the n-side electrode 129 can be suppressed.

In the manufacturing process of the second embodiment, the p-side ohmic electrode 51 of the blue-violet semiconductor laser device portion 110 in the wafer state is bonded to the surface of the p-type Ge substrate 50 through the fusible layer 1 in advance of the step of forming the n-side electrode 129, whereby the blue-violet semiconductor laser device portion 110 and the p-type Ge substrate 50 are bonded to each other by heating before forming the n-side electrode 129 requiring no thermal treatment step, and hence the n-side electrode 129 in which a thermal influence on the ohmic electrode layer 230 is reliably suppressed can be formed. Thus, a transferred-layer type semiconductor laser device 200 having the n-side electrode 129 obtaining excellent ohmic contact can be formed.

In the manufacturing process of the second embodiment, the n-type GaN substrate 11 is removed from the wafer of the blue-violet semiconductor laser device portion 110 bonded to the surface of the p-type Ge substrate 50 before forming the n-side electrode 129, whereby the n-side electrode 129 in which a thermal influence on the ohmic electrode layer 230 is reliably suppressed can be formed on the surface of the n-type GaN layer 61 with the n-type GaN substrate 11 removed. The remaining effects of the second embodiment is similar to those of the aforementioned first embodiment.

### Third Embodiment

A structure of a LED chip 300 according to a third embodiment of the present invention will be now described with reference to FIGS. 6, 10 and 11. According to the third embodiment, the present invention is applied to a transferred-layer type LED chip which is an exemplary nitride-based semiconductor device. The LED chip 300 is an example of the “semiconductor light-emitting device” in the present invention.

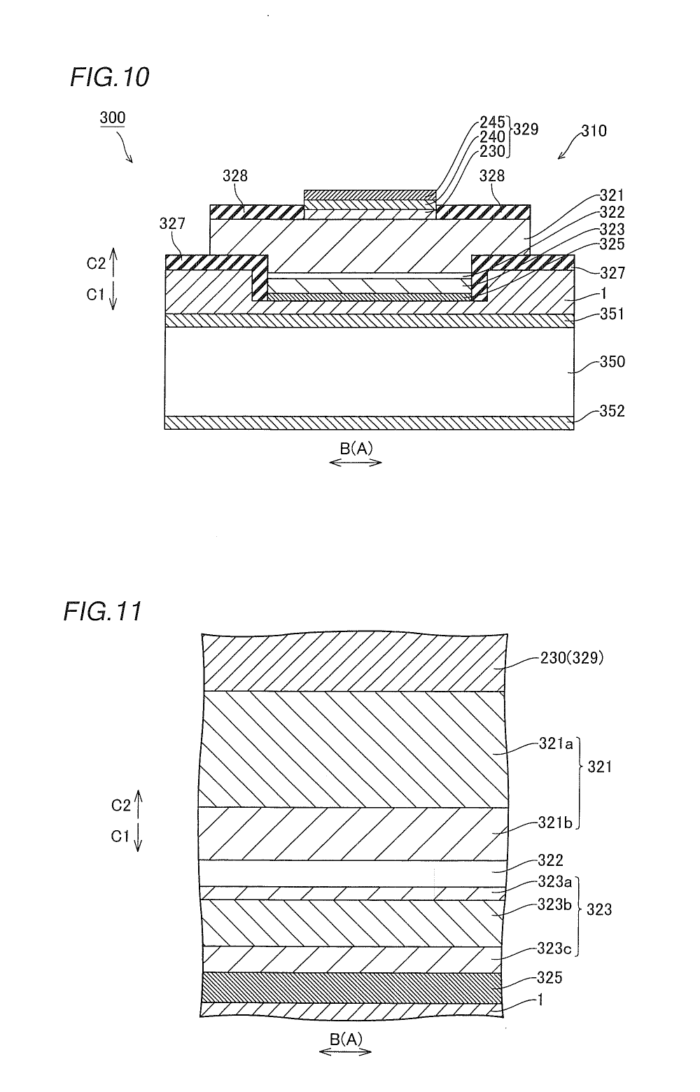

In the LED chip 300 according to the third embodiment of the present invention, a LED device portion 310 having a thickness of about 5 μm is bonded to an upper surface of the p-type Ge substrate 350 having a thickness of about 100 μm through a fusible layer 1, as shown in FIG. 10. The p-type Ge substrate 350 is an example of the “support substrate” in the present invention.

In the LED device portion 310, a light emitting layer 322 formed by alternately stacking four barrier layers (not shown) consisting of undoped single-crystalline Ga_{0.95}In_{0.05}N having a thickness of about 10 nm and three well layers (not shown) consisting of undoped single-crystalline Ga_{0.9}In_{0.1}N having a thickness of about 5 nm and a p-side semiconductor layer 323 are formed in this order on a lower surface of an n-side semiconductor layer 321, as shown in FIG. 10. A p-side ohmic electrode 325 made of a Pd layer, a Pt layer and an Au layer successively from a side closer to the p-side semiconductor layer 323 is formed on a lower surface of the p-side semiconductor layer 323. The n-side semiconductor layer 321 and the p-side semiconductor layer 323 are examples of the “n-type nitride-based semiconductor layer” and the “p-type nitride-based semiconductor layer” in the present invention, respectively.

In the n-side semiconductor layer 321, an n-type contact layer 321a made of Si-doped single-crystalline GaN having a thickness of about 0.5 μm and an n-type cladding layer 321b made of Si-doped single-crystalline Al_{0.1}Ga_{0.9}N having a thickness of about 0.15 μm from the upper layer toward the lower layer are stacked, as shown in FIG. 11. In the p-side semiconductor layer 323, a p-type cap layer 323a, a p-type cladding layer 323b made of Mg-doped single-crystalline Al_{0.1}Ga_{0.9}N having a thickness of about 0.1 μm and a p-type contact layer 323c made of undoped single-crystalline Ga_{0.95}In_{0.05}N having a thickness of about 5 nm from the upper layer toward the lower layer are stacked on a lower surface of the light emitting layer 322. The n-type contact layer 321a is an example of the “n-type nitride-based semiconductor layer” in the present invention.

As shown in FIG. 10, insulating films 327 made of SiO₂ are formed to cover both side surfaces of the p-side ohmic electrode 325, the p-side semiconductor layer 323 and the light emitting layer 322 and partial side surfaces and a lower surface of the n-side semiconductor layer 321. Insulating films 328 made of SiO₂ and an n-side electrode 329 are formed on an upper surface of the n-side semiconductor layer 321.

According to the third embodiment, the n-side electrode 329 has a structure in which an ohmic electrode layer 230, a barrier layer 240 and a pad electrode layer 245 are stacked successively from a side closer to the n-side semiconductor layer 321 (n-type contact layer 321a (see FIG. 11)), similarly to a case of the n-side electrode 129 in the aforementioned second embodiment shown in FIG. 6. In the ohmic electrode layer 230, an Al layer 231 (see FIG. 6) having a thickness of about 6 nm and an Hf layer 232 (see FIG. 6) having a thickness of about 10 nm are stacked on successively from a side closer to the n-type contact layer 321a (see FIG. 11). The Al layer 231 is formed in a state of being distributed in the form of islands on a surface of the n-type contact layer 321a. The Hf layer 232 covering the Al layer 231 is also formed on an interface between the n-type contact layer 321a and the ohmic electrode layer 230 to be in contact with the surface of the n-type contact layer 321a in addition to the Al layer 231 distributed in the form of islands.

A p-side Ge electrode 351 made of an Ni layer and an Au layer is formed successively from a side closer to the p-type Ge substrate 350 on a prescribed region of the upper surface of the p-type Ge substrate 350, as shown in FIG. 10. An anode-side electrode 352 made of an Ni layer and an Au layer is formed successively from a side closer to the p-type Ge substrate 350 on a lower surface of the p-type Ge substrate 350.

A manufacturing process for the LED chip 300 according to the third embodiment will be now described with reference to FIGS. 6 and 10 to 13.

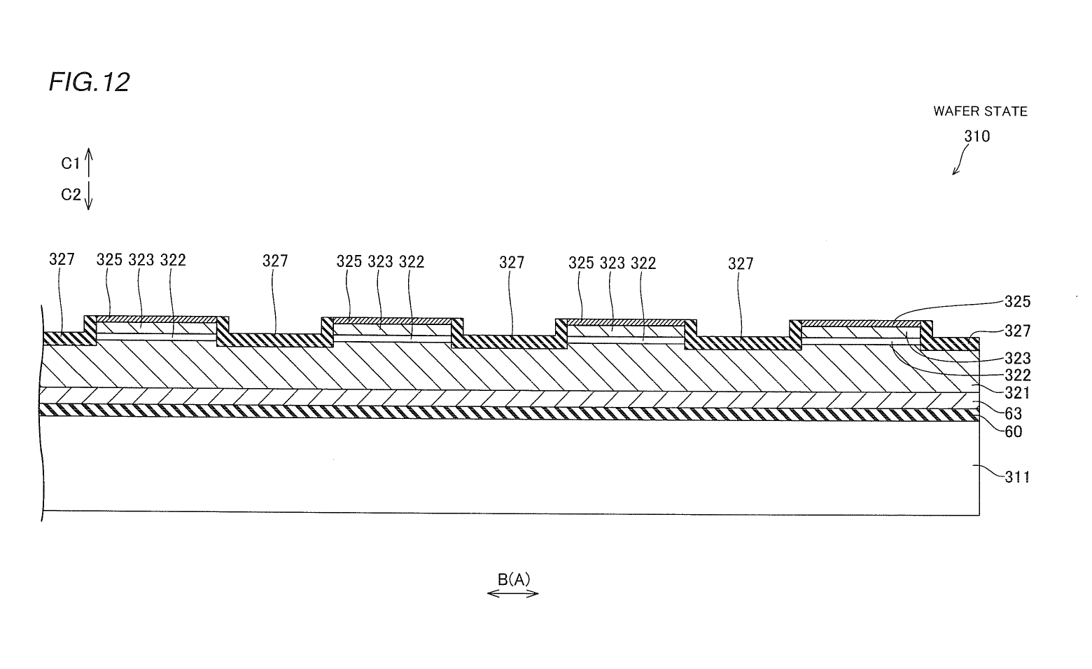

A separative layer 60, a buffer layer 63, the n-side semiconductor layer 321 (the n-type contact layer 321a and the n-type cladding layer 321b), the light emitting layer 322 and the p-side semiconductor layer 323 (the p-type cap layer 323a, the p-type cladding layer 323b and the p-type contact layer 323c) are successively stacked on an upper surface of an n-type GaN substrate 311 employing a manufacturing method similar to that of the aforementioned second embodiment as shown in FIG. 12.

Then, the p-side semiconductor layer 323 is converted to the p type by thermal treatment or electron beam treatment. Thereafter, the layers from the p-type contact layer 323c (see FIG. 11) to the n-side semiconductor layer 321 are partially etched to form the insulating films 327. The insulating films 327 on the p-type contact layer 323c are removed and the p-side ohmic electrode 325 is formed to be in contact with the p-type contact layer 323c. Thus, a wafer formed with the LED device portion 310 except the n-side electrode 329 is prepared (see FIG. 12).

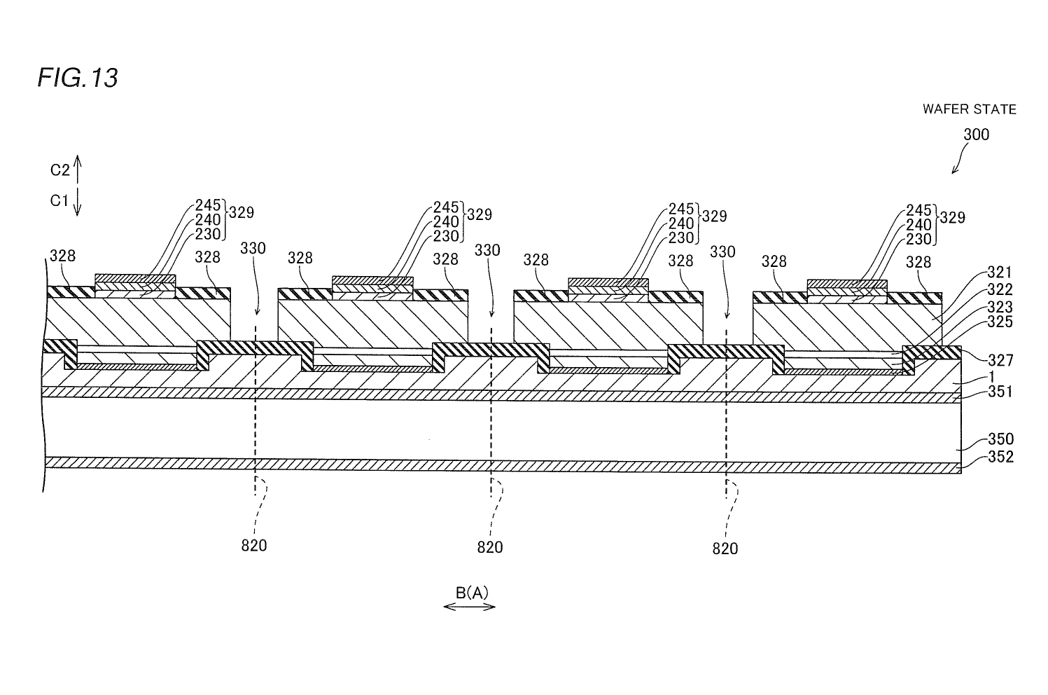

As shown in FIG. 13, the p-type Ge substrate 350 previously formed with the p-side Ge electrode 351 and the fusible layer 1, and the wafer formed with the LED device portion 310 are bonded to each other by the fusible layer 1 while being opposed to each other. Then, the separative layer 60 (see FIG. 12) is evaporated by a laser beam, to separate the n-type GaN substrate 311 (see FIG. 12). Thereafter, the buffer layer 63 (see FIG. 12) is removed by etching, and the patterned n-side electrode 329 is formed on a lower surface of the exposed n-type contact layer 321a (see FIG. 10) by vacuum chamber.

In the manufacturing process of the third embodiment, the Al layer 231 (see FIG. 6) having a thickness of about 6 nm is evaporated on the upper surface of the n-type contact layer 321a (see FIG. 11) held at about 30° C. in a vacuum by vacuum chamber. Thereafter, the ohmic electrode layer 230 is formed to cover the Al layer 231 distributed in the form of islands by evaporating the Hf layer 232 (see FIG. 6) to have a thickness of about 10 nm.

The Pt layer 241 (see FIG. 6) having a thickness of about 20 nm and the Pd layer 242 (see FIG. 6) having a thickness of about 20 nm are stacked in this order on the ohmic electrode layer 230, to form the barrier layer 240. The pad electrode layer 245 made of Au having a thickness of about 300 nm is formed on the barrier layer 240, to form the n-side electrode 329.

In other words, in the manufacturing process of the third embodiment, the wafer of the LED device portion 310 and the p-type Ge substrate 350 are bonded to each other by heating before forming the n-side electrode 329 requiring no thermal treatment step, and a Nd:YAG laser beam is applied, to separate the n-type GaN substrate 311 from the buffer layer 63.

Insulating films 328 (see FIG. 13) made of SiO₂ are formed on the n-side semiconductor layer 321 exposed from an n-side electrode 329. At this time, the partial insulating films 328 are removed on regions above the regions formed with the insulating films 327 by patterning so as to expose the n-side semiconductor layer 321.

As shown in FIG. 13, the anode-side electrode 352 made of the Ni layer and the Au layer is formed on the lower surface of the p-type Ge substrate 350 adjusted to have a thickness of about 100 μm. Thus, the LED chip 300 in a state of a wafer shown in FIG. 9 is formed.

Recess portions 330 extending in the form of a lattice in directions A and B and employed as device separation grooves are formed by employing the insulating films 328 on a side formed with the n-side electrode 329 as etching masks and etching prescribed regions of the n-side semiconductor layer 321 exposed from the insulating films 328. The recess portions 330 may be formed before the aforementioned step of forming the n-side electrode 329. Finally, the division of the wafer into device is performed on a position shown by along broken lines 820 (recess portions 330) along the direction A and B, thereby forming a large number of the LED chips 300 according to the third embodiment shown in FIG. 10.

According to the third embodiment, as hereinabove described, the LED chip 300 comprises the n-side electrode 329 including the Al layer 231 formed on the surface of the n-side semiconductor layer 321 (n-type contact layer 321a) and the Hf layer 232 formed to cover the surface of the Al layer 231 on a side opposite to the n-side semiconductor layer 321, whereby the n-side electrode 329 has the ohmic electrode layer 230 in which the Al layer 231 and the Hf layer 232 are stacked in this order on the surface of the n-side semiconductor layer 321 (n-type contact layer 321a) without alloying, and hence the n-side electrode 329 can be formed without requiring a thermal treatment step for alloying the Al layer 231 and the Hf layer 232 at a constant ratio by controlling a prescribed temperature condition or time after forming the p-side electrode or the electrode on the side of the p-type Ge substrate in the manufacturing process. A thermal treatment step is not performed in forming the n-side electrode 329, and hence no thermal influence is not given to the p-side ohmic electrode 325 or the p-side Ge electrode 351. Thus, deterioration of the p-side ohmic electrode 325 or p-side Ge electrode 351 due to a thermal treatment temperature is suppressed and hence increase in a voltage of the LED chip 300 in an LED operation is suppressed.

According to the third embodiment, the LED chip 300, to which the “n-side electrode” of the present invention is applied, is formed, whereby the transferred-layer type LED chip having the n-side electrode 329 obtaining excellent ohmic contact without thermal treatment (alloying) can be formed. The remaining effect of the third embodiment is similar to those of the aforementioned second embodiment.

### Fourth Embodiment

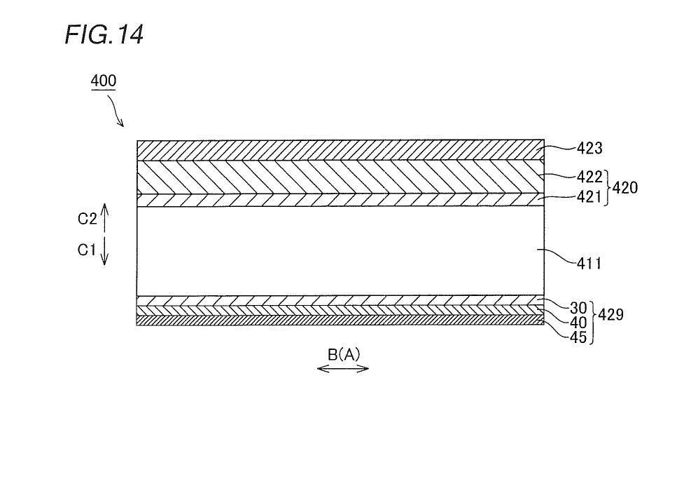

A structure of a solar cell device 400 according to a fourth embodiment of the present invention will be described with reference to FIGS. 2 and 14. According to the fourth embodiment, the present invention is applied to the solar cell device 400 which is an exemplary nitride-based semiconductor device.

In the solar cell device 400 according to the fourth embodiment of the present invention, a semiconductor layer 420 made of GaN is formed on an n-type GaN substrate 411 as shown in FIG. 14. In the semiconductor layer 420, an n-type GaN layer 421 made of undoped GaN and a p-type GaN layer 422 are formed. The n-type GaN substrate 411 is an example of the “n-type nitride-based semiconductor layer” in the present invention, and the p-type GaN layer 422 is an example of the “p-type nitride-based semiconductor layer” in the present invention. The semiconductor layer 420 is an example of the “nitride-based semiconductor” in the present invention.

As shown in FIG. 14, a p-side translucent electrode 423 made of ITO is formed on an upper surface of the semiconductor layer 420 (p-type GaN layer 422). An n-side electrode 429 serving as a back surface electrode is formed on a lower surface of the n-type GaN substrate 411.

According to the fourth embodiment, in the n-side electrode 429, an ohmic electrode layer 30, a barrier layer 40 and a pad electrode layer 45 are stacked successively from a side closer to the n-type GaN substrate 411, similarly to a case of the n-side electrode 29 in the aforementioned first embodiment shown in FIG. 2. The detailed structure (thicknesses and materials of the respective metal layers, and the like) of the n-side electrode 429 (see FIG. 2) is similar to that of the n-side electrode 29 (see FIG. 2) according to the aforementioned first embodiment.

In a manufacturing process of the solar cell device 400 according to the fourth embodiment, the n-type GaN layer 421 and the p-type GaN layer 422 are stacked on an upper surface of the n-type GaN substrate 411 to form the semiconductor layer 420 by employing a manufacturing method similar to that of the aforementioned first embodiment as shown in FIG. 14. Thereafter, the p-side translucent electrode 423 is formed on the semiconductor layer 420.

Then, the lower surface of the n-type GaN substrate 411 is so polished that the n-type GaN substrate 411 has a thickness of about 100 μm and a damage layer due to polishing is removed by dry etching, and the n-side electrode 429 is thereafter formed on the lower surface of the n-type GaN substrate 411. At this time, the n-side electrode 429 is formed through a manufacturing process similar to that of the aforementioned first embodiment. Thus, the solar cell device 400 in a state of wafer shown in FIG. 14 is formed.

According to the fourth embodiment, as hereinabove described, the solar cell device 400 comprises the n-side electrode 429 including the Al layer 31 (see FIG. 2) and the Hf layer 32 (see FIG. 2) formed on the lower surface of the n-type GaN substrate 411, whereby a thermal treatment step is not performed in forming the n-side electrode 429, and hence any thermal influence is not given to the p-side translucent electrode 423 in the manufacturing process. Thus, deterioration of the p-side translucent electrode 423 due to a thermal treatment temperature is suppressed.

According to the fourth embodiment, the solar cell device 400, to which the “n-side electrode” of the present invention is applied, is formed, whereby the solar cell device having the n-side electrode 429 obtaining excellent ohmic contact without thermal treatment (alloying) can be formed.

The remaining effects of the fourth embodiment are similar to those of the aforementioned first embodiment.

### Examples

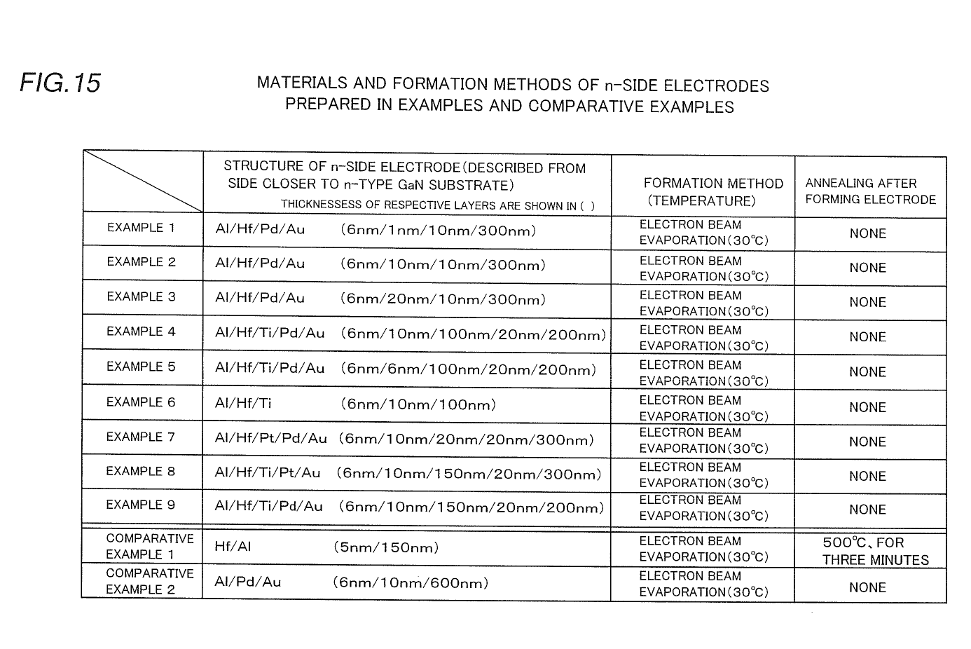

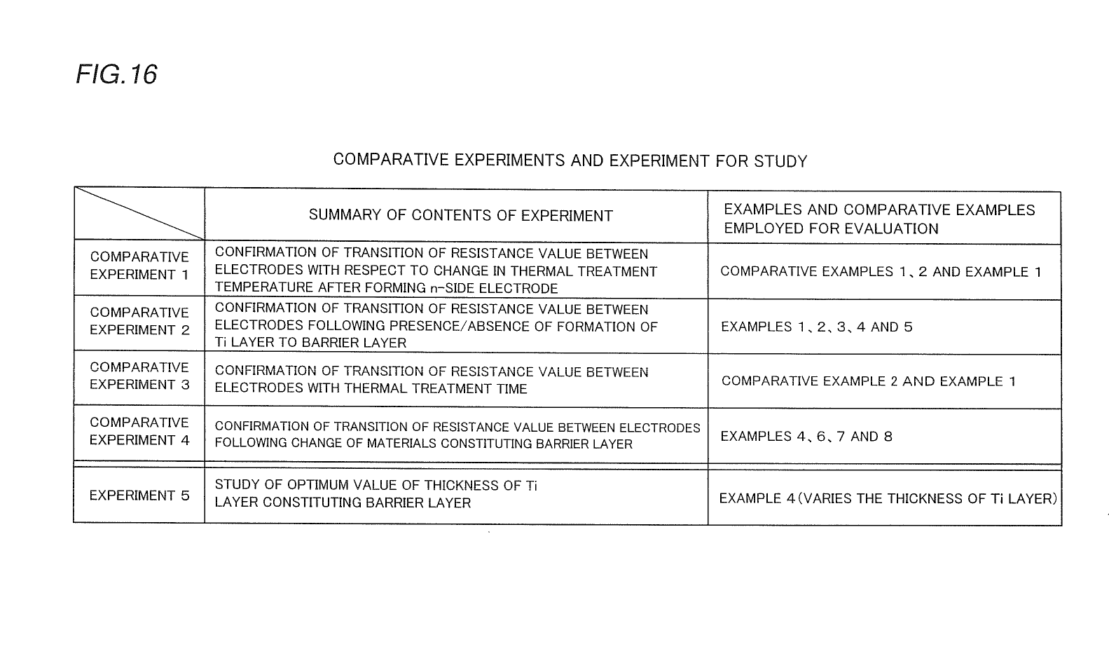

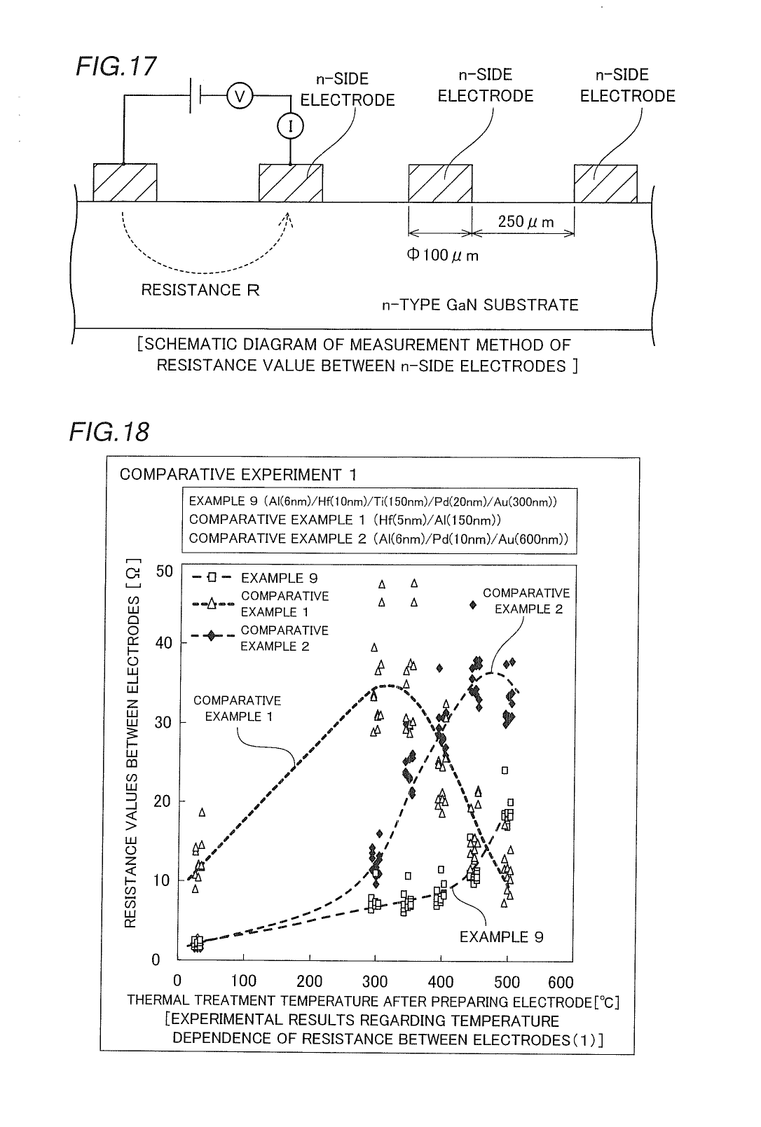

Comparative experiments conducted in order to confirm the effects of the aforementioned embodiments will be now described. In these comparative experiments, n-side electrodes according to the following Examples 1 to 9 were prepared as Examples corresponding to the aforementioned embodiments and n-side electrodes according to the following comparative examples 1 and 2 are prepared as comparative examples corresponding to the prior art, to investigate characteristics of the respective n-side electrodes. FIG. 15 shows materials and formation methods of the n-side electrodes prepared in the Examples and the comparative examples of the present invention, and FIG. 16 shows the contents of the comparative experiments in which the characteristics of the n-side electrodes were investigated. FIG. 17 schematically shows a method of measuring a resistance value between the n-side electrodes according to the comparative experiments shown in FIG. 16.

Preparation of the n-side electrodes according to Examples 1 to 9 corresponding to the aforementioned embodiments and the n-side electrodes according to comparative examples 1 and 2 corresponding to the prior art will be now described with reference to FIGS. 15 and 17.

### Example 1

Referring to FIGS. 15 and 17, in Example 1, respective metal layers for forming an n-side electrode was formed on an n-type GaN substrate having a surface previously cleaned by polishing and etching, electron beam evaporation. More specifically, an Al layer, an Hf layer, a Pd layer and an Au layer were stacked in this order on the n-type GaN substrate, to form the n-side electrode having a four-layer structure. Thicknesses of the respective layers were 6 nm (Al layer)/1 nm (Hf layer)/10 nm (Pd layer)/300 nm (Au layer) from on a side closer to the n-type GaN substrate. In the n-side electrode, the Al layer and the Hf layer are formed as an ohmic electrode layer, and the Pd layer and the Au layer are formed as a barrier layer and a pad electrode layer, respectively. A plurality of the (circular) n-side electrodes having a diameter of 100 μm in the form of dots were formed to be adjacent to each other at an interval of 250 μm in plan view.

### Example 2

In Example 2, an n-side electrode in which an Hf layer has a thickness different from that of the aforementioned Example 1 was formed. Thicknesses of the respective layers in Example 2 were 6 nm (Al layer)/10 nm (Hf layer)/10 nm (Pd layer)/300 nm (Au layer) from on a side closer to an n-type GaN substrate.

### Example 3

In Example 3, an n-side electrode in which an Hf layer has a thickness different from those of the aforementioned Examples 1 and 2 was formed. Thicknesses of the respective layers in Example 3 were 6 nm (Al layer)/20 nm (Hf layer)/10 nm (Pd layer)/300 nm (Au layer) from on a side closer to an n-type GaN substrate.

### Example 4

In Example 4, an n-side electrode in which an Hf layer has a thickness same as that of the aforementioned Example 2 and has a five-layer structure in which a Ti layer is newly added between the Hf layer and a Pd layer was formed. Thicknesses of the respective layers in Example 4 were 6 nm (Al layer)/10 nm (Hf layer)/100 nm (Ti layer)/20 nm (Pd layer)/200 nm (Au layer) from on a side closer to an n-type GaN substrate. In the n-side electrode, the Al layer and the Hf layer were formed as an ohmic electrode layer and the Ti layer and the Pd layer were formed as a barrier layer.

### Example 5

In Example 5, an n-side electrode in which an Hf layer has a thickness different from those of the aforementioned Examples 1 to 4 while having a five-layer structure in which a Ti layer is added between the Hf layer and a Pd layer was formed, similarly to the aforementioned Example 4. Thicknesses of the respective layers in Example 5 were 6 nm (Al layer)/6 nm (Hf layer)/100 nm (Ti layer)/20 nm (Pd layer)/200 nm (Au layer) from on a side closer to an n-type GaN substrate.

### Example 6

In Example 6, a structure of a pad electrode layer in an n-side electrode was different in materials and thicknesses from those of the aforementioned Examples 4 and 5. The structure and thicknesses of respective layers according to Example 6 were 6 nm (Al layer)/10 nm (Hf layer)/100 nm (Ti layer) from on a side closer to an n-type GaN substrate. In Example 6, the pad electrode layer was formed only by the Ti layer.

### Example 7

In Example 7, a structure of a pad electrode layer in an n-side electrode was different in materials and thicknesses from those of the aforementioned Examples 4 to 6. The structure and thicknesses of respective layers according to Example 7 were 6 nm (Al layer)/10 nm (Hf layer)/20 nm (Pt layer)/20 nm (Pd layer)/300 nm (Au layer) from on a side closer to an n-type GaN substrate. In Example 7, a barrier layer was formed by the Pt layer and the Pd layer, and the pad electrode layer was formed by the Au layer.

### Example 8

In Example 8, a structure of a pad electrode layer in an n-side electrode was different in materials and thicknesses from those of the aforementioned Examples 4 to 7. The structure and thicknesses of respective layers according to Example 8 were 6 nm (Al layer)/10 nm (Hf layer)/150 nm (Ti layer)/20 nm (Pt layer)/300 nm (Au layer) from on a side closer to an n-type GaN substrate. In Example 8, a barrier layer was formed by the Ti layer and the Pt layer, and the pad electrode layer was formed by the Au layer.

### Example 9

In Example 9, a Ti layer is formed to have a thickness of 150 nm, and an Au layer was formed to have a thickness of 300 nm, to form an n-side electrode, dissimilarly to Example 4. Therefore, thicknesses of the respective layers in Example 9 were 6 nm (Al layer)/10 nm (Hf layer)/150 nm (Ti layer)/20 nm (Pd layer)/300 nm (Au layer) from on a side closer to an n-type GaN substrate.

### Comparative Example 1

In comparative example 1 with respect to the aforementioned Examples 1 to 9, an Hf layer and an Al layer were stacked in this order on an n-type GaN substrate, to form an n-side electrode having a two-layer structure. More specifically, the Hf layer having a thickness of 5 nm and the Al layer having a thickness of 150 nm were stacked successively from a side closer to the n-type GaN substrate. The n-side electrode was formed by annealing the stacked electrode layers for 3 minutes under a temperature condition of 500° C. In other words, in comparative example 1, the prepared n-side electrode was formed as an n-side electrode in contact with a surface of the n-type GaN substrate in a state where Hf and Al are alloyed in the vicinity of an interface of the n-type GaN substrate and the Hf layer, dissimilarly to Examples 1 to 9.

### Comparative Example 2

In comparative example 2, an Al layer, a Pd layer and an Au layer were stacked in this order on an n-type GaN substrate, to form an n-side electrode having a three-layer structure. Thicknesses of the respective layers were about 6 nm (Al layer)/10 nm (Pd layer)/600 nm (Au layer) from on a side closer to an n-type GaN substrate. In other words, in comparative example 2, the n-side electrode was formed by forming an ohmic electrode layer having no Hf layer and constituted only by the Al layer dissimilarly to Examples 1 to 9.

Comparative experiments 1 to 4 conducted for investigating the characteristics of the n-side electrodes according to the aforementioned Examples 1 to 9 and the n-side electrodes according to the aforementioned comparative examples 1 and 2 will be now described with reference to FIGS. 16 to 22.

In the aforementioned comparative experiments 1 to 4, applied voltages of the n-side electrode according to Examples 1 to 9 and the n-side electrode according to the comparative examples 1 and 2 used in the comparative experiments in flowing a current of 100 mA between adjacent pairs of electrodes in the form of dots were measured, to measure resistance values between the pairs electrode (see FIG. 17). Data of the resistance values between electrodes was obtained substrate by measuring the resistance values between adjacent pairs of electrodes at arbitrary positions (twelve portions) on the n-type GaN.

In comparative experiment 1, transition of thermal treatment temperatures after preparing electrodes and the resistance values between electrodes following the thermal treatment were investigated by employing the n-side electrodes prepared as the aforementioned Example 9, and comparative examples 1 and 2, as shown in FIG. 18. In the n-side electrodes according to the aforementioned comparative examples 1, it has been confirmed that the resistance values between electrodes tended to increase with increase of the thermal treatment temperature, while the Hf layers and the Al layers are partially alloyed with each other at thermal treatment temperatures of about 400° C. to 500° C. due to influence of annealing, to reduce the resistance values between electrodes. In the n-side electrodes according to the aforementioned comparative examples 2, it has been confirmed that the resistance values between electrodes tended to increase with increase of the thermal treatment temperature. Particularly, it has been confirmed that increase of the resistance values between electrodes was further remarkable at a thermal treatment temperature of 300° C. or more and ohmic characteristics of the n-side electrodes were deteriorated with increase of the thermal treatment temperature.

On the other hand, in the n-side electrodes according to the aforementioned Example 9, it has been confirmed that the resistance values between electrodes tended to increase with increase of the thermal treatment temperature, while the resistance values between electrodes were lower than the resistance values between electrodes of the n-side electrodes according to the aforementioned comparative examples 1 and 2 in a temperature range of up to 450° C. Thus, it has been confirmed that in the n-side electrodes according to the aforementioned Example 9 in which the Ti layer (thickness of 150 nm) is interposed as the barrier layer, deterioration (increase of the resistance values) of the ohmic characteristics of the n-side electrodes following increase of the thermal treatment temperature was suppressed as compared with the n-side electrodes according to the aforementioned comparative examples 1 and 2.

As to the resistance values between electrodes immediately after preparing the electrodes of the aforementioned Example 9, it has been confirmed that the resistance values between electrodes was about 20% of the resistance values between electrodes after preparing the electrodes of the aforementioned comparative examples 1. It has been confirmed that current-voltage characteristics after preparing the n-side electrodes according to the aforementioned comparative examples 1 showed non-ohmic characteristics show by a solid line 500 in FIG. 22, while the current-voltage characteristics immediately after preparing the n-side electrodes according to the aforementioned Example 9 have ohmic characteristics shown by a solid line 700 in FIG. 22.

In the n-side electrodes according to the aforementioned Example 9, it has been confirmed that the resistance values between electrodes were reduced as compared with those of the n-side electrodes according to the aforementioned comparative examples 1 and 2 when the thermal treatment temperature was in the wide range from the temperature after preparing the electrodes to about 450° C., and hence ohmic characteristics can be maintained in the wider range of the thermal treatment temperature as compared with those of the n-side electrodes according to the aforementioned comparative examples 1 and 2. Therefore, the semiconductor device maintaining the ohmic characteristic of the n-side electrode can be conceivably formed also when the semiconductor device is subjected to the prescribed manufacturing process under a higher temperature condition than that in forming the n-side electrode (die-bonding by AuSn solder, or a heat treatment step at about 200° C. to about 300° C. such as a photolithography step or a baking step, or a step of wire-bonding to the n-side electrode 29).

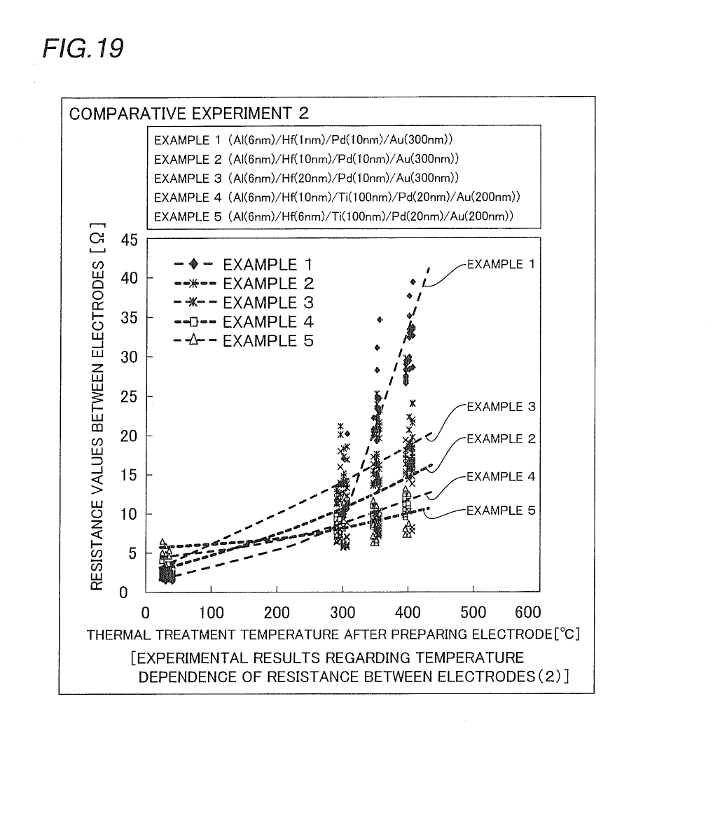

In comparative experiment 2, the characteristics of the n-side electrodes were investigated by employing the n-side electrodes prepared as the aforementioned Examples 1 to 5 by an experimental method similar to that of comparative example 1, as shown in FIG. 19. In the n-side electrodes according to the aforementioned Example 1, it has been confirmed that the resistance values between electrodes tended to increase with increase of the thermal treatment temperature. On the other hand, in the n-side electrodes, having the thicknesses of the Hf layers changed to 10 nm and 20 nm respectively, according to the aforementioned Example 2 and 3, it has been confirmed that the resistance values between electrodes tended to increase with increase of the thermal treatment temperature, while the resistance values between electrodes were lower than those of the n-side electrodes, having the thickness of the Hf layer of 1 nm, according to the aforementioned Example 1.

According to the aforementioned Examples 4 and 5, in the n-side electrodes where the Ti layers having a thickness of 100 nm were interposed between the Hf layers and the Pd layers, it has been confirmed that the resistance values between electrodes tended to increase with increase of the thermal treatment temperature, while the resistance values were further reduced as compared with those of the aforementioned Example 2 and 3. Thus, it has been confirmed again that the Ti layers were interposed in the pad electrode layers (barrier layers), and hence deterioration (increase of the resistance values) of the n-side electrodes following increase of the thermal treatment temperature was suppressed.

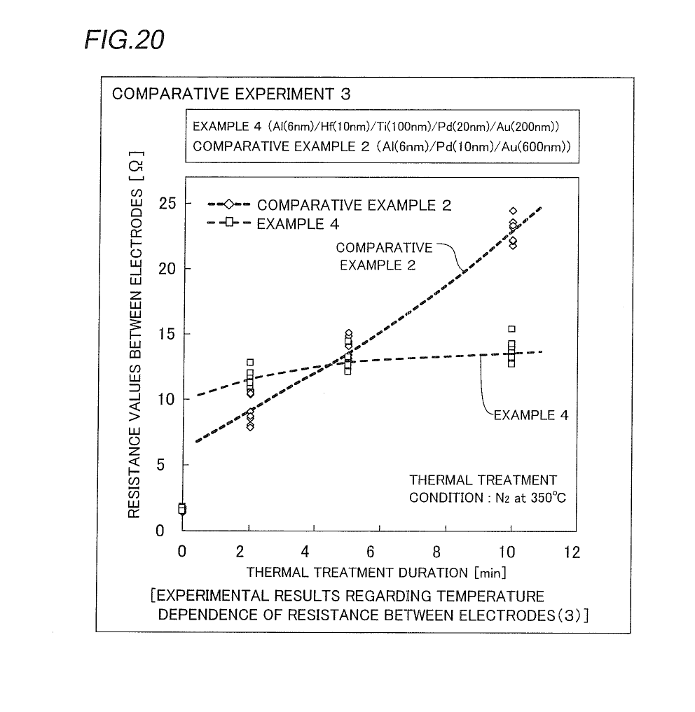

In comparative experiment 3, transition of thermal treatment time after preparing electrodes and the resistance values between electrodes following the thermal treatment were investigated by employing the n-side electrodes prepared as the aforementioned Example 4 and comparative example 2, as shown in FIG. 20. Resistance values between the electrodes in a case where the n-side electrodes were allowed to stand in a nitrogen atmosphere at a thermal treatment temperature of 350° C. for prescribed time were measured. In the n-side electrodes, having no Ti layer, according to the aforementioned comparative example 2, it has been confirmed that the resistance values between electrodes were monotonically increased with thermal treatment time.

On the other hand, in the n-side electrodes according to the aforementioned Example 4, it has been confirmed that the resistance values between electrodes tended to slightly increase with thermal treatment time, while the increase tendency was slow (in a saturated state) after 4 minutes. Therefore, the n-side electrodes, having the Ti layers as the barrier layers, according to the aforementioned Example 4 were conceivably more competitive not only in thermal treatment temperature but also in thermal treatment time than the n-side electrodes, having no Ti layer as the barrier layer, according to the aforementioned comparative example 2, because ohmic characteristics are difficult to be deteriorated.

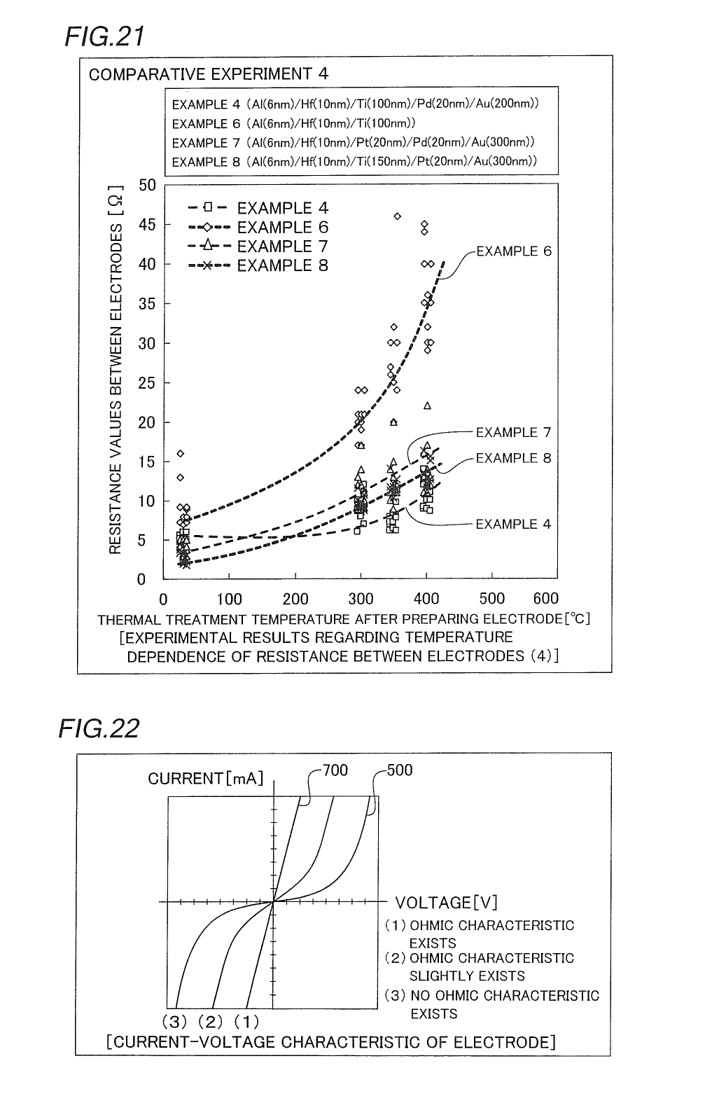

In the comparative experiment 4, transition of thermal treatment temperatures after preparing electrodes and the resistance values between electrodes following the thermal treatment was investigated by employing the n-side electrodes prepared as the aforementioned Examples 4, 6, 7 and 8 through an experimental method similar to comparative experiment 1, as shown in FIG. 21. In the comparative experiment 4, thermal treatment temperature dependence of resistance values between electrodes in a case where combination of materials of the barrier layers formed on the ohmic electrode layers consisting of the Al layers and Hf layers were different was investigated.

In the n-side electrodes according to the aforementioned Example 6, it has been confirmed that the barrier layers were constituted only by the Ti layers having a thickness of 100 nm and hence resistance values between electrodes tended to increase following increase of thermal treatment temperature, as shown in FIG. 21. On the other hand, in the n-side electrodes according to the aforementioned Examples 4, 7 and 8, it has been confirmed that although the structures of the respective barrier layers were different, each barrier layer was constituted by a plurality of layers including at least a single layer of the Ti layer or the Pt layer, and hence resistance values between electrodes lower than those of the n-side electrodes, having the barrier layers constituted only by the Ti layers, according to the aforementioned Example 6 were obtained. As shown in FIG. 21, in the n-side electrodes according to the aforementioned Examples 4, 7 and 8, it has been confirmed that the ratios of the resistance values between electrodes following increase of the thermal treatment temperature of the n-side electrodes according to the aforementioned Example 4 were the smallest.

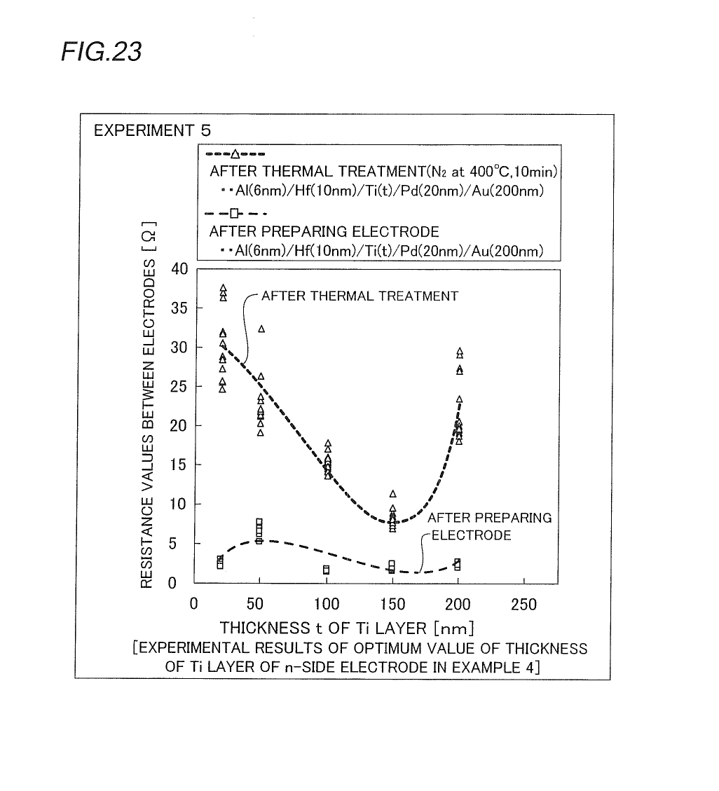

Experiment 5 conducted for investigating an optimum value of thicknesses of the Ti layers constituting the n-side electrodes according to the aforementioned Example 4 will be now described with reference to FIGS. 16 and 23.

In the aforementioned experiment 5 (see FIG. 16), resistance values between electrodes immediately after preparing the n-side electrodes according to the aforementioned Example 4 by changing the thicknesses of the Ti layers and resistance values between electrodes in a case where the n-side electrodes according to the aforementioned Example 4 were allowed to stand in a nitrogen atmosphere at a thermal treatment temperature of 400° C. for 10 minutes were measured. The thickness t of each Ti layer is varied in five different ways, namely 20 nm, 50 nm, 100 nm, 150 nm and 200 nm, while the thicknesses of other layers (the Al layer, the Hf layer, the Pd layer and the Au layer) were constant (Al layer: 6 nm, Hf layer: 10 nm, Pd layer: 20 nm, Au layer: 200 nm), to conduct the experiment.

In the aforementioned experiment 5, it has been confirmed that resistance values between electrodes tended to be the lowest when the thicknesses t of the Ti layers were about 150 nm in both of a condition of immediately after preparing the n-side electrodes and a condition in a nitrogen atmosphere at 400° C., as shown in FIG. 23. Therefore, in each n-side electrode according to the aforementioned Example 4, it has been proved that the Ti layer in the barrier layer was formed to preferably have the thickness t of at least 100 nm and not more than 150 nm (more preferably have about 150 nm). Each n-side electrode so formed that the thickness of the Ti layers is 150 nm is shown as the aforementioned Example 9 (see FIG. 13).

Referring to FIGS. 15, 24 and 25, operation test 6 was conducted for characteristics (voltages) of the devices in a case where the n-side electrodes with optimum thicknesses of metal layers (Ti layers) constituting the electrodes confirmed on the bases of the aforementioned comparative experiments 1 to 4 and experiment 5 were applied to the blue-violet semiconductor laser devices.

Deterioration of an ohmic characteristic of an electrode due to thermal influence is known as a factor influencing a voltage of the blue-violet semiconductor laser device. In other words, in a step of assembling the laser device, a device chip and a submount are bonded to each other in a state of fusing AuSn solder in die-bonding. At this time, the device is bonded under a temperature condition of at least a melting point (278° C.) of the AuSn solder, and hence the ohmic characteristic of the electrode is deteriorated when a temperature (heat) in bonding affects the electrode (n-side electrode). In the following operation test 6, voltage characteristics in a case where semiconductor laser devices assembled by applying the n-side electrodes according to the aforementioned Examples and semiconductor laser device assembled by applying the n-side electrodes according to the aforementioned comparative corresponding to the prior art were driven in the same current condition were measured, thereby investigating thermal influences on the laser device chips in assembling the semiconductor laser devices.

In operation test 6, the n-side electrode (see FIG. 15) according to the aforementioned Example 9 and the n-side electrode (see FIG. 15) according to the aforementioned comparative example 2 were applied to prepare chips of the blue-violet semiconductor laser devices by a manufacturing process similar to the aforementioned first embodiment. Six laser device chips were prepared by applying the n-side electrodes according to the aforementioned Example 9, and five laser device chips were prepared by applying the n-side electrodes according to the aforementioned comparative example 2. All of the laser device chips were obtained from the same wafer. Sides of the n-side electrodes of the respective laser device chips were bonded to submounts by AuSn solder and wire-bonded, and the laser device chips were mounted with window caps to prepare the blue-violet semiconductor laser devices.

Each of the prepared laser device chips was formed to have a cavity length of 925 μm and a device width of 200 μm (a ridge width is about 1.2 μm). As to each p-side electrode, a Ti layer (thickness: 10 nm), a Pd layer (thickness: 150 nm) and an Au layer (thickness: 2 μm) were stacked on a p-side electrode formed by stacking a Pt layer (thickness: 1 nm), a Pd layer (thickness: 15 nm) and a Pt layer (thickness: 25 nm) successively from a side closer to an active layer, to form a pad electrode. Each n-side electrode was formed to have an electrode width of 150 μm with respect to a device width of 200 μm by a lift-off method in forming a wafer. No protective film was formed on cavity facets of the laser device chips after cleavage in the form of a bar.

The respective blue-violet semiconductor laser devices were placed in a constant temperature reservoir adjusted to 70° C., to measure voltages (Vop) when a current (Iop) increased to 100 mA to 160 mA in a stepwise fashion. Measurement of voltages was performed until a total operation time reached 1100 hours.

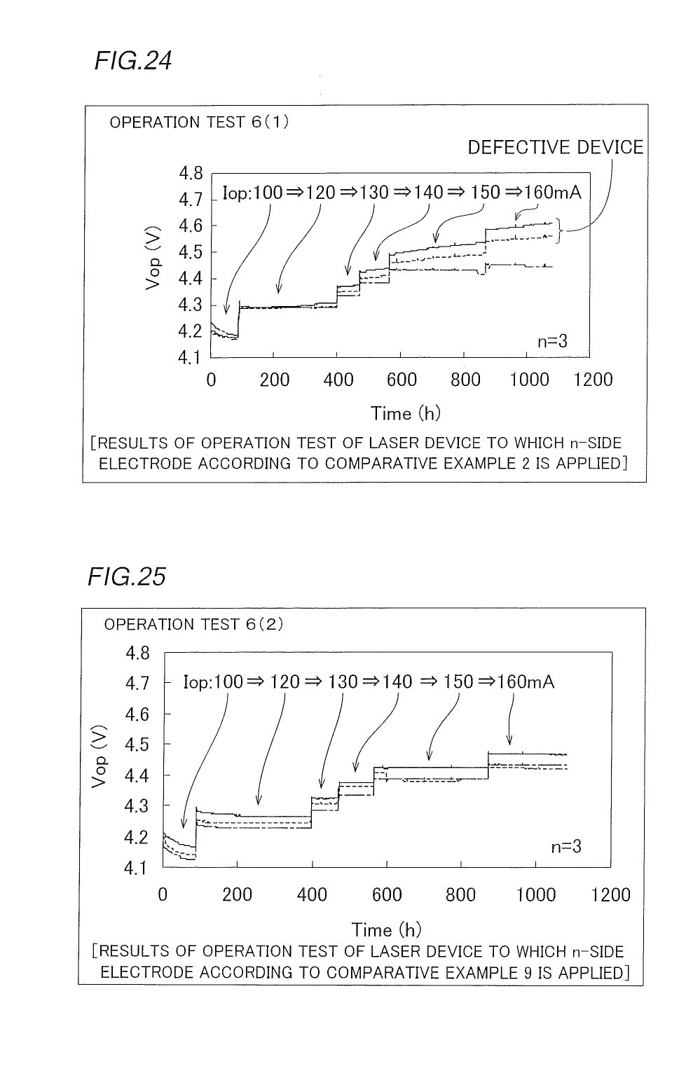

According to the aforementioned operation test 6, in each laser device chip, to which the n-side electrodes according to the aforementioned comparative example 2 was applied, a Vop in the each current condition tended to gradually increase with time following gradual increase of the Iop, as in the results shown in FIG. 24. The result that the amount of the increased voltage is increased as the current is increased was obtained. On the other hand, in each laser device chip, to which the n-side electrode according to the aforementioned Example 9 was applied, the Vop in each current condition tended not to increase with time even when the Iop is gradually increase, as in the results shown in FIG. 25. It has been confirmed that this tendency did not depend on the current. As a result obtained from the measurement data, as to deviation of the Vop for operation time (1100 hours), the results shown in FIG. 24 (comparative examples 2) were in the range of 0.2 V to 0.42 V, while the results shown in FIG. 25 (Example 9) were in the range of 0.22 V to 0.25 V. From these, in each laser device chip, to which the n-side electrode according to the aforementioned Example 9 was applied, it has been confirmed that the increased amount of the voltage with respect to the current is lower than that of each laser device chip, to which the n-side electrode according to the comparative example 2 was applied, by about 0.2 V.

From the above results in operation test 6, in each laser device chip, to which the n-side electrode according to the aforementioned Example 9 was applied, it has been confirmed that increase of a voltage applied to the ohmic electrode layer (the Al layer (thickness: 6 nm) and the Hf layer (thickness: 10 nm)) formed on the lower surface of the n-type GaN substrate is suppressed by the Ti layer (thickness: 150 nm) serving as the barrier layer also in a state where a current is increased to increase a laser device temperature, and hence it has been confirmed that an excellent ohmic characteristic of the n-side electrode can be maintained. Additionally, it has been confirmed that Hf which was a metal having a high melting point was employed in the ohmic electrode layer, and hence an ohmic characteristic was not deteriorated without thermal influence following increase of the laser device temperature.

In the aforementioned operation test 6, the voltages of the two laser device chips out of the 5 laser device chips prepared by applying the n-side electrodes according to the aforementioned comparative example 2 devices abruptly increased at an early stage immediately after start of the operation test due to deterioration of the p-side electrode. Therefore, the results in FIG. 24 has showed that the Vop of the 2 devices out of 3 devices actually tested were increased with the increase of the Iop. The voltages of the 3 devices out of the 6 laser device chips prepared by applying the n-side electrodes according to the aforementioned Example 9 abruptly increased at an early stage immediately after start of the operation test due to deterioration of the p-side electrode. Therefore, the results in FIG. 25 has showed that the Vop of all of the tested 3 devices was not increased with time even when the Iop in the respective current conditions was gradually increased.

Although the present invention has been described and illustrated in detail, it is clearly understood that the same is by way of illustration and example only and is not to be taken by way of limitation, the spirit and scope of the present invention being limited only by the terms of the appended claims.

For example, while the barrier layer 40 (240) is constituted by the Ti layer (Pt layer), the Pd layer and the Au layer in each of the aforementioned first and the second embodiments, the present invention is not restricted to this but the pad electrode layer may be formed by replacing the Pd layer with the Ni layer.

While the barrier layer 40 (240) includes either the Ti layer or the Pt layer in each of the aforementioned first and the second embodiments, the present invention is not restricted to this but the barrier layer 40 may include both metal layers of the Ti layer and the Pt layer.

While the p-type Ge substrate 50 is employed as the support substrate of the blue-violet semiconductor laser device portion 110 in the aforementioned second embodiments, the present invention is not restricted to this but a GaP substrate, an Si substrate and a GaAs substrate may be employed as the support substrate.

While the n-type GaN substrate 11 is employed as the growth substrate of the semiconductor device layer in the aforementioned second embodiments, the present invention is not restricted to this but a sapphire substrate may be employed as the growth substrate.

While the n-side electrode of the present invention is applied to the semiconductor laser device or the LED chip in each of the aforementioned first to third embodiments, the present invention is not restricted to this but the n-side electrode of the present invention may be employed for a semiconductor device such as a transistor other than the light emitting device such as the semiconductor laser device or the LED chip.

What is claimed is:

1. A nitride-based semiconductor device comprising:
an n-type nitride-based semiconductor layer; and
an n-side electrode including a first metal layer made of Al, formed on a surface of said n-type nitride-based semiconductor layer and a second metal layer made of Hf formed so as to cover a surface of said first metal layer on a side opposite to said n-type nitride-based semiconductor layer.

2. The nitride-based semiconductor device according to claim 1, wherein
said first metal layer is formed to partially cover the surface of said n-type nitride-based semiconductor layer, and
said second metal layer is formed to cover the surface of said first metal layer, and a surface, not covered by said first metal layer, of said n-type nitride-based semiconductor layer.

3. The nitride-based semiconductor device according to claim 2, wherein
said first metal layer is formed in a state where Al is distributed in the form of islands or a state where Al is in the form of a net.

4. The nitride-based semiconductor device according to claim 3, wherein
a thickness of said islandlike or netlike first metal layer is at most about 10 nm.

5. The nitride-based semiconductor device according to claim 3, wherein
said second metal layer is formed to be in contact with the surface of said islandlike or netlike first metal layer and the surface, not covered by said first metal layer, of said n-type nitride-based semiconductor layer.

6. The nitride-based semiconductor device according to claim 5, wherein
a thickness of said second metal layer is at least about 2 nm and not more than about 20 nm.

7. The nitride-based semiconductor device according to claim 1, wherein
said n-side electrode further includes a third metal layer made of Pd, formed on a side of said second metal layer opposite to a side formed with said first metal layer.

8. The nitride-based semiconductor device according to claim 7, wherein
said n-side electrode further includes a fourth metal layer formed between said second metal layer and said third metal layer, and
said fourth metal layer includes at least either Ti or Pt.

9. The nitride-based semiconductor device according to claim 8, wherein
a thickness of said fourth metal layer is larger than a thickness of said third metal layer.

10. The nitride-based semiconductor device according to claim 8, wherein
said fourth metal layer is made of Ti, and
a thickness of said fourth metal layer is at least about 100 nm and not more than about 150 nm.

11. The nitride-based semiconductor device according to claim 1,
said n-side electrode further includes a pad electrode layer containing Au, formed on a side of said second metal layer opposite to said first metal layer.

12. The nitride-based semiconductor device according to claim 1, further comprising:
a light emitting layer formed on a surface of said n-type nitride-based semiconductor layer on a side opposite to said n-side electrode; and
a p-type nitride-based semiconductor layer formed on a surface of said light emitting layer, wherein
said nitride-based semiconductor device is a semiconductor light-emitting device including said n-type nitride-based semiconductor layer, said light emitting layer and said p-type nitride-based semiconductor layer.

13. The nitride-based semiconductor device according to claim 1, further comprising a p-type nitride-based semiconductor layer formed on a surface of said n-type nitride-based semiconductor layer on a side opposite to said n-side electrode, wherein
said nitride-based semiconductor device is a solar cell device including said n-type nitride-based semiconductor layer and said p-type nitride-based semiconductor layer.

14. A method of manufacturing a nitride-based semiconductor device, comprising steps of:
forming an n-type nitride-based semiconductor layer; and
forming an n-side electrode by stacking a first metal layer made of Al and a second metal layer made of Hf covering a surface of said first metal layer on a side opposite to said n-type nitride-based semiconductor layer on a surface of said n-type nitride-based semiconductor layer.

15. The method of manufacturing a nitride-based semiconductor device according to claim 14, wherein
said step of forming said n-side electrode includes a step of forming said first metal layer so as to partially cover the surface of said n-type nitride-based semiconductor layer and a step of forming said second metal layer so as to cover the surface of said first metal layer and a surface, not covered by said first metal layer, of said n-type nitride-based semiconductor layer.

16. The method of manufacturing a nitride-based semiconductor device according to claim 14, further comprising steps of:
forming a semiconductor light-emitting device by stacking a light emitting layer and a p-type nitride-based semiconductor layer on a surface of said n-type nitride-based semiconductor layer on a side opposite to a side formed with said n-side electrode; and
bonding a surface of said semiconductor light-emitting device on a side of said p-type nitride-based semiconductor layer to a surface of a support substrate in advance of said step of forming said n-side electrode.

17. The method of manufacturing a nitride-based semiconductor device according to claim 16, wherein
said step of forming said n-type nitride-based semiconductor layer includes a step of forming said n-type nitride-based semiconductor layer on a surface of a growth substrate,
further comprising a step of removing said growth substrate from said semiconductor light-emitting device bonded on said surface of said support substrate in advance of said step of forming said n-side electrode.

18. The method of manufacturing a nitride-based semiconductor device according to claim 14, wherein
said step of forming said n-side electrode includes a step of forming said n-side electrode without thermal treatment after stacking said first and second metal layers.

19. The method of manufacturing a nitride-based semiconductor device according to claim 14, further comprising:
a step of thinning of said n-type semiconductor layer from a side of said surface of said n-type nitride-based semiconductor layer in advance of said step of forming said n-side electrode, and
a step of removing a surface layer generated on said surface of said n-type nitride-based semiconductor layer by thinning.

20. A method of manufacturing a nitride-based semiconductor device, comprising steps of:
forming a nitride-based semiconductor stacked with an n-type nitride-based semiconductor layer and a p-type nitride-based semiconductor layer;
forming a p-side electrode on a surface of said p-type nitride-based semiconductor layer; and
forming an n-side electrode after said step of forming said p-side electrode, wherein
said step of forming said n-side electrode includes a step of forming said n-side electrode by stacking a first metal layer made of Al and a second metal layer made of Hf covering a surface of said first metal layer on a side opposite to said n-type nitride-based semiconductor layer on a surface of said n-type nitride-based semiconductor layer.
